(19) United States
(12) Patent Application Publication
(10) Pub. No.: US 2013/0137244 A1
(43) Pub. Date: May 30, 2013

(54) METHOD AND APPARATUS FOR RECONDITIONING A CARRIER WAFER FOR REUSE

(71) Applicants: Karl-Josef Kramer, San Jose, CA (US); Mehrdad M. Moslehi, Los Altos, CA (US)

(72) Inventors: Karl-Josef Kramer, San Jose, CA (US); Mehrdad M. Moslehi, Los Altos, CA (US)

(73) Assignee: SOLEXEL, INC., Milpitas, CA (US)

(21) Appl. No.: 13/482,963

(22) Filed: May 29, 2012

Related U.S. Application Data
(63) Continuation-in-part of application No. 13/341,976, filed on Dec. 31, 2011.
Application No. 13/341,976 is a continuation-in-part of application No. 13/209,390, filed on Aug. 13, 2011.
(60) Provisional application No. 61/490,562, filed on May 26, 2011.

(51) Int. Cl. H01L 21/02

(52) U.S. Cl. CPC H01L 21/02664
USPC 438/478

(57) ABSTRACT

The disclosed subject matter pertains to deposition of thin film or thin foil materials in general, but more specifically to deposition of epitaxial monocrystalline or quasi-monocrystalline silicon film (epi film) for use in manufacturing of high efficiency solar cells. In operation, methods are disclosed which extend the reusable life and to reduce the amortized cost of a reusable substrate or template used in the manufacturing process of silicon and other semiconductor solar cells.

### CROSS-REFERENCE TO RELATED APPLICATIONS

This application claims priority to U.S. Provisional Patent Application Ser. No. 61/490,562 filed May 26, 2011, which is hereby incorporated by reference in its entirety.

This application is also a continuation-in-part of U.S. patent application Ser. No. 13/341,976 filed Dec. 31, 2012, and a continuation-in-part of U.S. patent application Ser. No. 13/209,390, filed Aug. 13, 2011, both which are hereby incorporated by reference in their entirety.

### FIELD

This disclosure relates in general to the field of solar photovoltaics, and more particularly to the field of repeatedly fabricating thin film solar substrates using a semiconductor template.

### BACKGROUND

Crystalline silicon (including multi- and mono-crystalline silicon) is the most dominant absorber material for commercial photovoltaic applications. The relatively high efficiencies associated with mass-produced crystalline silicon solar cells, combined with the abundance of material, garner appeal for continued use and advancement. But the relatively high cost of crystalline silicon material itself limits the widespread use of these solar modules. At present, the cost of “wafering”, or crystallizing silicon and cutting a wafer, accounts for about 40% to 60% of the finished solar module manufacturing cost. If a more direct way of making wafers were possible, great headway could be made in lowering the cost of solar cells.

There are several known methods of growing monocrystalline or quasi-monocrystalline semiconductors, such as silicon, and releasing or transferring the grown wafer. Regardless of the methods, a low cost epitaxial silicon deposition process accompanied by a high-volume, production-worthy, low cost method of forming a release (sacrificial lift-off separation) layer are prerequisites for wider use of silicon solar cells.

Another prerequisite is the availability of a re-usable template to repeatedly perform the sequence of release layer formation, thin film deposition, on-template processing, thin film layer release, recovery/reconditioning of template.

The microelectronics industry achieves economy of scale through obtaining greater yield by increasing the number of die (or chips) per wafer, scaling the wafer size, and enhancing the chip functionality (or integration density) with each successive new product generation. In the solar industry, economy is achieved through the industrialization of solar cell and module manufacturing processes with low cost high productivity equipment. Further economies are achieved through price reduction in raw materials through reduction of materials used per watt output of solar cells (also through elimination of consumption of expensive materials and replacing them with cheaper materials).

In order to achieve the necessary economy for the solar photovoltaics industry, process cost modeling is studied to identify and optimize equipment performance. Several categories of cost make up the total cost picture: Fixed Cost (FC), Recurring Cost (RC) and Yield Cost (YC). FC is made up of items such as equipment purchase price, installation cost and robotics or automation cost. RC is largely made up of electricity, gases, chemicals, operator salaries and maintenance technician support. YC may be interpreted as the total value of parts lost during production.

To achieve reduced Cost of Ownership (CoO) numbers required by the solar field, all aspects of the cost picture must be optimized. The qualities of a low cost process are (in order of priority): 1) High productivity, 2) High yield, 3) Low RC, and 4) Low FC.

Designing highly productive and economical methods and process equipment requires a good understanding of the process requirements and reflecting those requirements into the equipment architecture. High yield requires a robust process and reliable equipment and as equipment productivity increases, so too does yield cost. Low RC is also a prerequisite for overall low CoO. RC can impact plant site selection based on, for example, cost of local power or availability of bulk chemicals. FC, although important, is diluted by equipment productivity.

Thus, a high productivity, reliable, efficient manufacturing process flow and equipment is a prerequisite for low cost solar cells.

### SUMMARY

Therefore a need has arisen for high productivity thin film deposition methods and systems. In accordance with the disclosed subject matter, methods for the reconstruction of a reusable semiconductor template which provide significant cost reduction in the production of thin film semiconductor substrates (TFSSs) are disclosed.

The disclosed subject matter pertains to deposition of thin film or thin foil materials in general, but more specifically to deposition of epitaxial monocrystalline or quasi-monocrystalline silicon film (epi film) for use in manufacturing of high efficiency solar cells. In operation, methods are disclosed which extend the reusable life and to reduce the amortized cost of a substrate or template used in the manufacturing process of silicon solar cells. In one embodiment, this comprises grinding the reusable template to remove deposited residue.

These and other advantages of the disclosed subject matter, as well as additional novel features, will be apparent from the description provided herein. The intent of this summary is not to be a comprehensive description of the subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages included within this description be within the scope of the claims.

### BRIEF DESCRIPTION OF THE DRAWINGS

The features, nature, and advantages of the disclosed subject matter will become more apparent from the detailed description set forth below when taken in conjunction with the drawings, in which like reference numerals indicate like features and wherein:

FIGS. 1A-1C show one embodiment of the formation of surface features on a reusable semiconductor template;

FIG. 2A shows a patterned semiconductor template, a porous semiconductor multilayer, and a TFSS;

FIG. 2B shows an electron micrograph of a flat template and a sacrificial layer with two different porosities;

FIG. 3A shows a hexagonal patterned semiconductor template, a porous semiconductor multilayer, and a TFSS;

FIG. 3B is a photograph of the released hexagonal TFSS of FIG. 3A;

FIG. 4 shows an electron micrograph of the interface between a template and a TFSS;

FIG. 5 shows a TFSS ready to be released from a template;

FIG. 6A shows two templates with differing amounts of TFSS overdeposition;

FIG. 6B shows a TFSS being released from a template;

FIG. 6C shows a TFSS with overdeposition being removed from a template;

FIG. 6D shows the use of grinding tape to remove residual TFSS material from a template;

FIG. 6E shows the use of an edge grinder to remove residual TFSS material from a template;

FIG. 6F shows the use of a laser with a varying angle of incidence to remove residual TFSS material from a template;

FIG. 6G shows the removal of excess front-side TFSS material by grinding;

FIG. 7A-C depict main process steps of a three-dimensionally structured template as it is reconstructed in accordance with the disclosed subject matter;

FIG. 8A-B depict main process steps of a three-dimensionally structured template as it is reconstructed to mitigate a defective region;

FIG. 9A-C depict key fabrication steps of the reconditioning of a wafer in accordance with the disclosed subject matter;

FIGS. 10A and 10B are two process flow embodiments describing the major fabrication steps for manufacturing high efficiency crystalline thin film solar cells in accordance with the disclosed subject matter;

FIGS. 11A and 11B are cross sectional views of a template in accordance with the disclosed subject matter;

FIG. 12 is a cross section view of a template after multiple re-use cycles;

FIG. 13 is a cross section view of a template in anodization equipment;

FIGS. 14 and 15 are diagrams of two parallel bevel grinding embodiments in accordance with the disclosed subject matter;

FIGS. 16A, 16B, and 16C are diagrams of a device removing the residue from a template;

FIGS. 17A and 17B are diagrams showing a device for removing residue with a strong holding force;

FIG. 18 is a diagram illustrating a thermally induced cleave stopped on the release layer; and

FIG. 19 is a process flow illustrating an embodiment of a structure for solar cell thin semiconductor film edge trimming.

### DETAILED DESCRIPTION

Although the present subject matter is described with reference to specific embodiments, one skilled in the art could apply the principles discussed herein to other areas and/or embodiments without undue experimentation.

In operation, and particularly in the field of photovoltaics, the disclosed subject matter enables low cost fabrication of thin film substrates to be used for solar cell manufacturing by means of a template which can be used repeatedly to fabricate the thin film substrates. The field of this disclosure covers several apparatuses and methods for generating thin film substrates and for treating the templates which are used to produce the thin film substrates, with the goal of recovering the templates to enable an extended number of re-uses.

A process to produce thin film or thin foil epitaxial solar cells includes the use of single crystal silicon or suitable crystalline semiconductor material wafers as reusable templates. This disclosure includes process flows, methods, apparatuses, and variations thereof which enables the repeated use of a template that is used in the fabrication of thin film layers which subsequently are processed to become solar cells.

The subject matter of this disclosure may include a starting crystalline semiconductor wafer (called a template) with correct resistivity to enable anodization to form porous semiconductor material on one or both sides. The semiconductors used may include crystalline silicon, and in particular monocrystalline silicon. The template outline may be of any suitable shape, including round (with or without notches or flats), square, or pseudo-square with rounded, truncated, or chamfered corners; and the template may also be planar, substantially planar, or have a three-dimensional structure. The porous semiconductor material may consist of several layers with discrete or graded porosity. At least one section of the porous semiconductor layer system serves as a designated weakened layer that facilitates separation of the TFSS from the template.

This disclosure covers the use of a reusable template for repeatedly fabricating thin crystalline solar cell substrates from the template—during which the solar cell substrates may be fabricated on one side of the template or on both sides of the template. And even though the figures in this disclosure specifically address the single sided processing, it is envisioned that all embodiments of the current disclosure hold essentially for the case of single sided substrate processing as well as for double side substrate processing using both sides of the template to harvest solar cell substrates.

Regarding the starting wafer, several structural architecture options are described in the following; however the wafer and resulting template may be in any form, planar, textured, or having any three-dimensional structure. In the simplest embodiment, the template may be essentially flat, i.e. the surface may be of any chosen surface quality, such as for example as-sawn with saw damage removed, lapped or ground, etched, grinded, or even mirror polished. In another embodiment, the wafer may be textured, using for instance alkaline random texturing before the formation of the above-described porous semiconductor layer system. By this means, a textured surface is then transferred directly onto the thin film solar cell substrate. As a third alternative, the template may be a three-dimensional structure generated using processing such as patterned wet or dry etching. This template with three-dimensional pattern may be achieved through the use of patterning technology, such as, but not exclusively, photolithography and wet or dry etching.

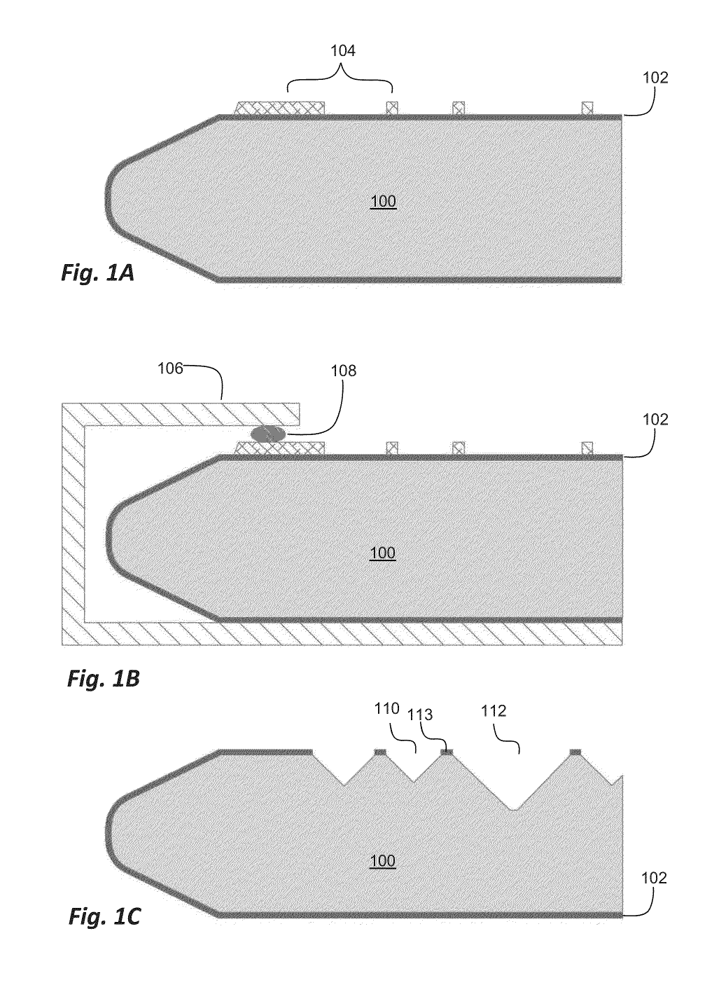

An example process is described in FIGS. 1A-1C for the formation of a three-dimensional template. In FIG. 1A, a starting wafer 100 is provided. For the purpose of forming a 3-dimensional structure, typically, a hard mask is formed, using as materials for example, but not exclusively, thermal oxide or other deposited etch resistant layer or layers such as deposited silicon nitride or silicon di-oxide. Shown, hard mask layer SiO₂ 102, is formed on the surface of wafer 100. Then the desired pattern of photoresist 104 is lithographically patterned onto hard mask layer 102. In FIG. 1B, the wafer is placed in a holder/chamber 106 and sealed with O-ring 108 to protect all but the front surface. Then hard mask layer 102 is etched to produce the desired pattern, removing all hard mask except what lies underneath the remaining photoresist.

In FIG. 1C, a semiconductor etch process is employed, either through dry etching, such as deep reactive ion etching (DRIE), or wet etching such as using an optionally heated concentrated alkaline wet etch with chemicals such as potassium hydroxide, sodium hydroxide, tetramethyl ammonium hydroxide (TMAH) or others. This creates the desired pattern on the surrface of the wafer—as shown in the example of FIG. 1C which includes large inverted pyramidal structures 112 and small pyramidal structures 110 defined by ridges 113. Finally, the photoresist and hard mask are stripped from the wafer, and the wafer is cleaned. It is then ready for the formation of porous semiconductor on the textured surface. Other similar processes are easily derived from the figures by those skilled in the art.

A three-dimensional template patterning is depicted in most figures of this disclosure as it encompasses a larger realm of embodiments. However, unless otherwise noted, the figures, process flows, methods and apparatuses of this disclosure are equally applicable to flat or randomly textured templates.

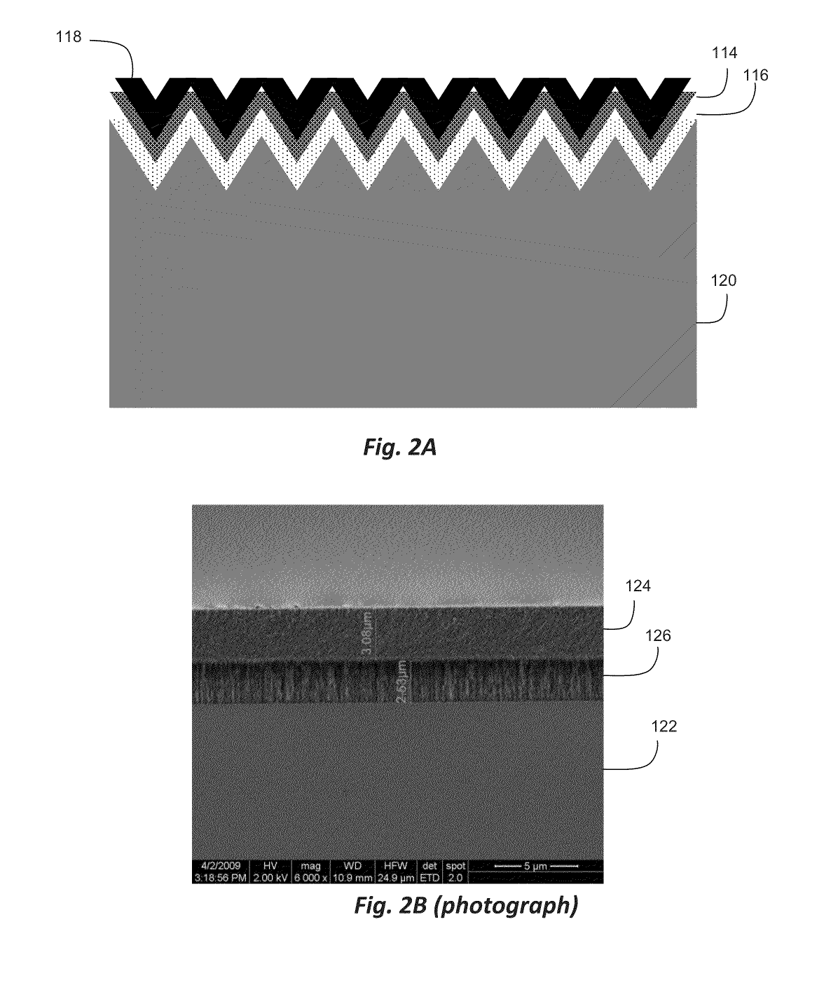

Using either a patterned or an un-patterned template, the subsequent process step is porous semiconductor formation (by anodization such as a wet anodic etch in an HF-based chemistry), followed by rinsing and drying where necessary. Porous semiconductor such as porous silicon on a crystalline silicon template is to be formed on at least one side of the template. In the case that the semiconductor is silicon, the process of forming porous silicon has been described in previous disclosures, for example U.S. Patent Publication No. 2011/0030610, which is hereby incorporated by reference. As shown in FIG. 2A, the porous semiconductor formation may entail the fabrication of at least one low current, lower porosity region 114 at the surface and at least one high current, higher porosity layer 116 closer to template 120. Importanly, a single porosity layer or a graded porosity layer may also be employed.

The template, having the porous semiconductor layers formed, may then be transferred to an epitaxial deposition reactor, in which an epitaxial layer is deposited at least on one side of the template. FIG. 2A illustrates the deposition of epitaxial layer 118 on top of the porous semiconductor layer system. FIG. 2B is a photograph of a porous semiconductor bi-layer structure on flat template 122, with lower porosity layer 124 on top and higher porosity 126 below.

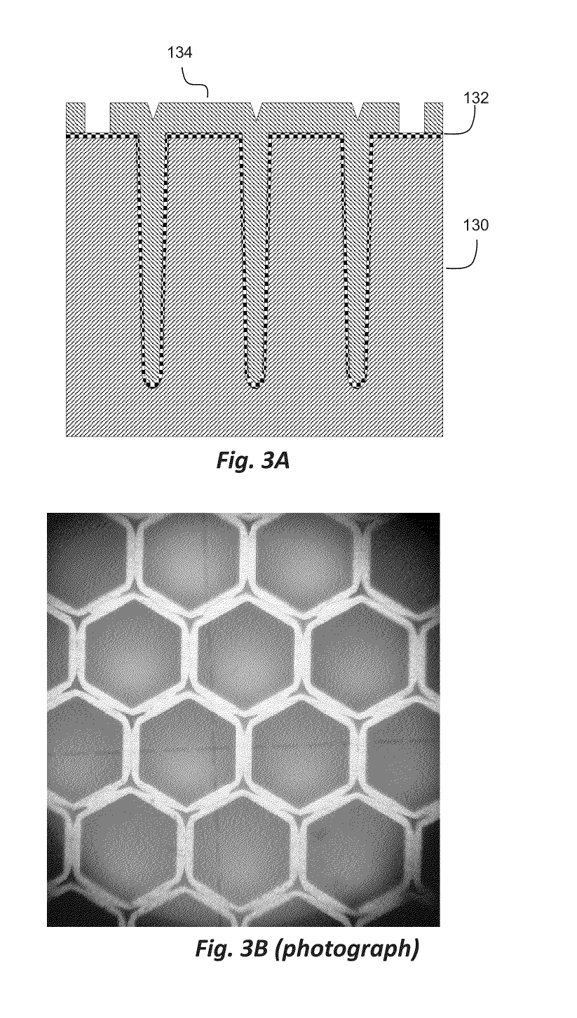

FIG. 3A is a drawing illustrating the deposition of epitaxial silicon layer 134 on porous silicon layer 132 formed on three-dimensional hexagonal template 130. FIG. 3B is a top view photograph of a released epitaxial thin film silicon layer, such as epitaxial silicon layer 134 in FIG. 3A, after release from the hexagonal template.

Before the epitaxial deposition, either during the ramp-up phase or during a separate pre-deposition time, the template is heated in a hydrogen ambient which serves several purposes: the top layer of the porous semiconductor is reflowed to re-form a quasi-monocrystalline growth surface and ultrathin seed layer of semiconductor (QMS). Also, the hydrogen bake serves to reduce any oxidized surface semiconductor back to its elemental form. In addition, the high porosity semiconductor layer coalesces to form a weak layer which can later serve as the release boundary between the grown layer and the template.

If the semiconductor is silicon, then in the initial stages of the deposition or during the bake, the reflow can be assisted by small amounts of a non-chlorine-containing species such as silane or using very low flow quantities of other silicon-containing gases such as trichlorosilane (TCS). This is one option for a process component that serves to safely prevent a failure mechanism that may occur during imperfect reflow and which is described below. Other problems and failure mechanisms that may occur during reflow have been described U.S. patent application Ser. No. 13/209,390 filed on Aug. 13, 2011 which is hereby incorporated by reference.

There are potential failure mechanisms that may occur during reflow. Solutions to such failure mechanisms are part of this disclosure: as the template is heated up in the semiconductor deposition reactor, which can for example be an epitaxial reactor, the template touches the susceptor typically in a plurality of locations. These contact points can contribute to a non-ideality in the above-described reflow of the porous semiconductor layer. These contact points may also contribute to a local abrasion of the porous semiconductor layer. As a consequence, the porous semiconductor layer may contain local areas where it is not hermetic.

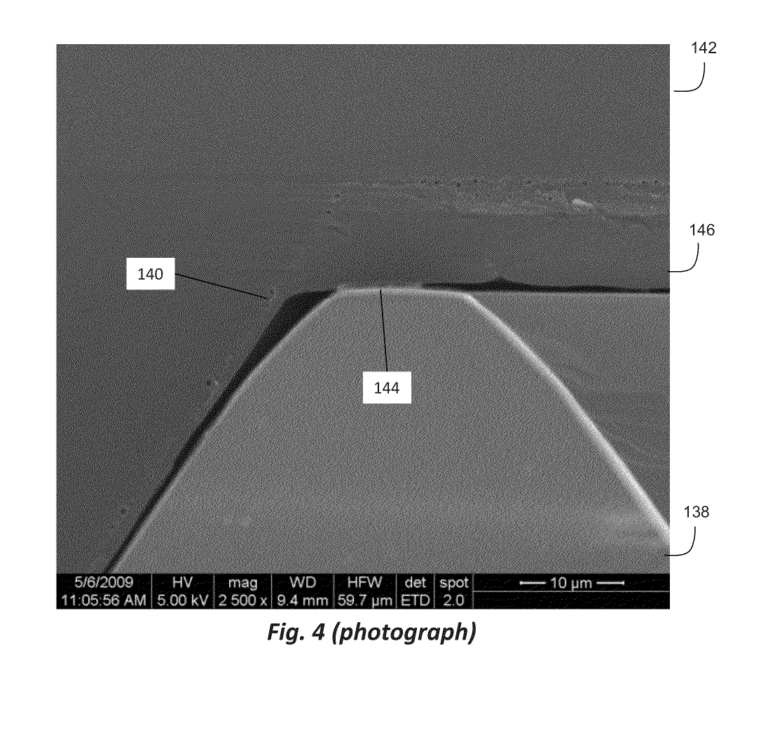

An example of a failure mechanism is illustrated in the photograph of FIG. 4, which shows template 138, QMS layer 140 (which normally contains some entrapped holes), and deposited epitaxial layer 142. As the deposition starts after the reflow, two phenomena can be observed: a) deposition of material through QMS layer 140 and directly onto the template base. Fused spot 144 is an example of this phenomenon. Such areas lack a weakened sub-layer and thus resist the subsequent release process (described below). In cases where shortly after the onset of deposition, the non-hermetic region is sealed, there is a chance that deposition gas may be trapped in underneath the top deposition layer. Such deposition gases may contain etching components such as chlorine-containing species as byproducts of the deposition reaction of silicon from a TCS molecule. These byproducts can contribute to subsequent etching of the template material. The etched and volatized template material can redeposit on the top layer, thus re-releasing again the chlorine-containing species. In FIG. 4, some re-deposited template material 146 may be seen. Thus, in a quasi-sealed local environment the process can continue and template etching can be observed to be severe, up to several microns. One option to avoid this etching and re-deposition mechanism is to start the deposition using a reactant which does not have an etching species as a byproduct. An example for such a reactant is silane, in the case of silicon deposition. Another option to avoid both the deposition directly onto the template and the local etching of the template is the proper formation of the contact area that the template shares with the susceptor. Low contact area in conjunction with suitably large radii at the contact area are preferable. This, in conjunction with suitable heater arrangements, is required to enable a uniform thermal ramp and profile within and between templates.

As for the epitaxial deposition process, the TFSS that is deposited epitaxially may contain an in-situ emitter, deposited in situ in the semiconductor deposition chamber. The emitter may also be added later as an ex-situ emitter outside of the epitaxy chamber. The structure on the template may be with the emitter up (emitter last during deposition) or down (emitter first during deposition). The epitaxial or non-epitaxial deposition may or may not contain a suitable dopant gradient designed to aid the desired flow of generated carriers through the device.

This so fabricated layer structure of deposited semiconductor on a weakened layer on a high temperature capable template is extremely valuable. It allows for carrying a thin film on a solid template and allows much flexibility for what is in the following called on-template processing.

In such on-template processing, the template serves as a carrier to move and support the thin and fragile TFSS throughout several on-template process steps, including but not limited to the following: thermal processes such as oxidation or film deposition, including but not limited to thermal oxidation; pulsed nanosecond (ns), pulsed picoseconds (ps) or other laser processes, such as scribing, doping, or ablation; chemical vapor deposition (CVD) and physical vapor deposition (PVD) processes; lithography, screen printing, stencil printing, ink jet printing, aerosol printing, spray coating or etching, ion implantation, immersion or single side clean, etch or deposition (such as plating), lamination, die attach or bonding, releasing, wet chemical texturing or dry texturing of the surface, rinsing, cleaning and drying of the surface. A unique quality here is that the template is clean and solar-cell-compatible, rigid and sturdy, high-temperature-capable, and reworkable.

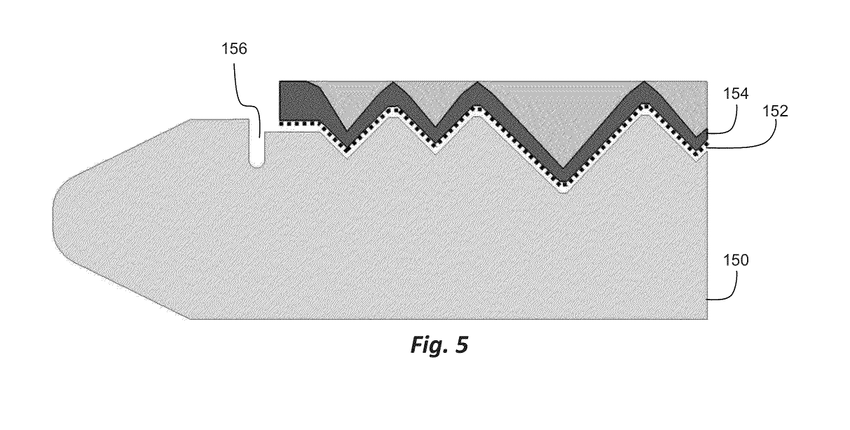

After suitable on-template processing, the TFSS can be released from the template carrier (optionally after its reinforcement with a backplane sheet laminated to, coated or printed on or otherwise applied to the TFSS). A conceptual diagram of the release of TFSS 154 from template 150 along sacrificial porous layer 152 is shown in FIG. 5. The release can be carried out either with or without the use of a temporary or permanent reinforcement plate or sheet, which is attached to the epi layer prior to the epi release. The reinforcement plate or sheet may or may not at this point or later contain structures, such as dielectrics or electrically conductive cell interconnect materials. If used, the reinforcement plate may contain perforations or otherwise a plurality of electrically conductive locations enabling the electrical contacting of the TFSS through or around the reinforcement plate, such perforations being present either at the time of TFSS release or formed at a later point. Suitable reinforcement materials may include silicon, glass, silicon-aluminum alloys, plastics or polymers such as prepreg or other dielectric adhesives, metals such as aluminum, ceramics or combinations thereof. At a suitable point prior to release, the definition or border cutting of the TFSS area to be released can be accomplished for instance using a laser. FIG. 4 shows border cut 156 surrounding TFSS 154.

This border cutting can be performed before or after the release of the TFSS. It may be advantageous to do cutting both before and after the release, depending on reinforcement process and materials. The border cutting also serves to weaken the thin TFSS and thus facilitate easier release. Another potential method for facilitating easier release is the use of a grinding or otherwise abrasive method, preferably applied to the edge of the template. By doing so, the TFSS epitaxial layer region at the edge of the template can serve as the weak point, from which release can be initiated. Such pre-release grinding can also facilitate the flow of air into the weakened area between TFSS 154 and template 150, thereby allowing pressure equalization and removing pressure-differential-induced resistance to the release motion. The release itself can be carried out by exploiting the presence of local weak areas which serve as initiation locations for the release.

Optionally, a pulsed force, for instance by pulsating the vacuum on either side of the template and substrate sandwich, can be applied. In this way, the release process can be extended across location and time (not unlike opening a zipper), rather than having to overcome the whole area bond force plus the atmospheric pressure holding force on the template. Alternatively, the release can be initiated at an edge or a corner of a substrate and then proceed from there, while in the process keeping the template and the partially released TFSS essentially parallel, in order to avoid small curvature radii, which can contribute to excessive stresses and potential cracking of the active TFSS layer.

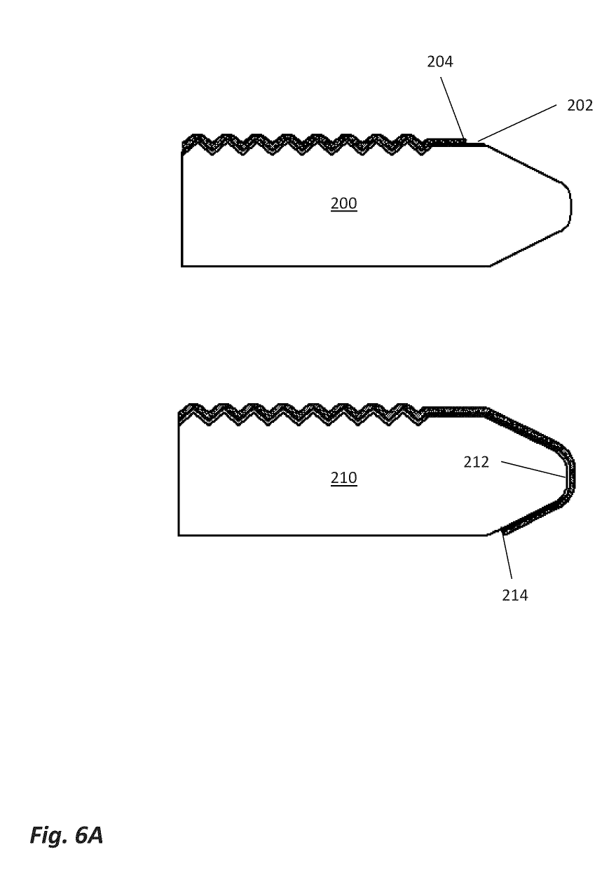

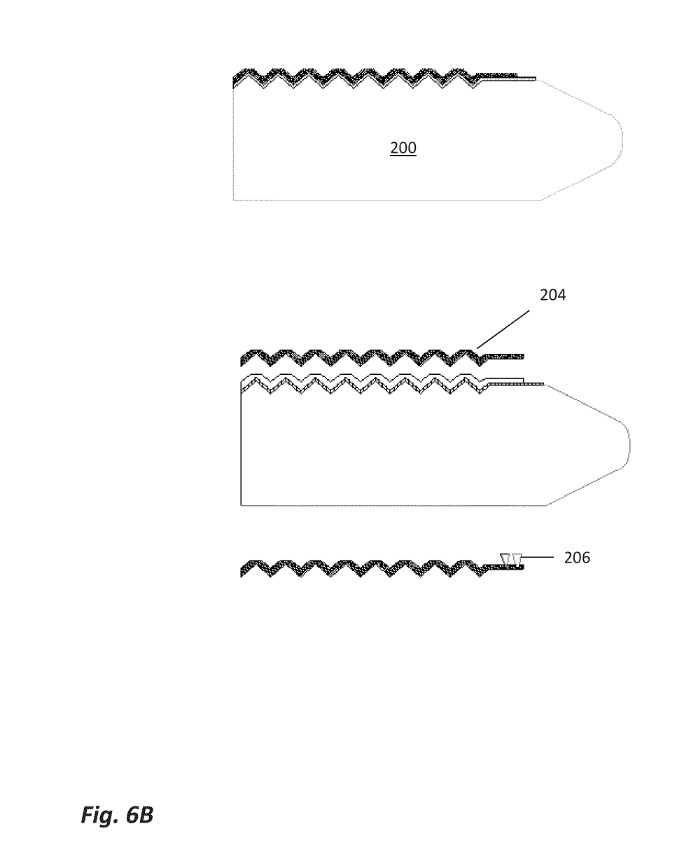

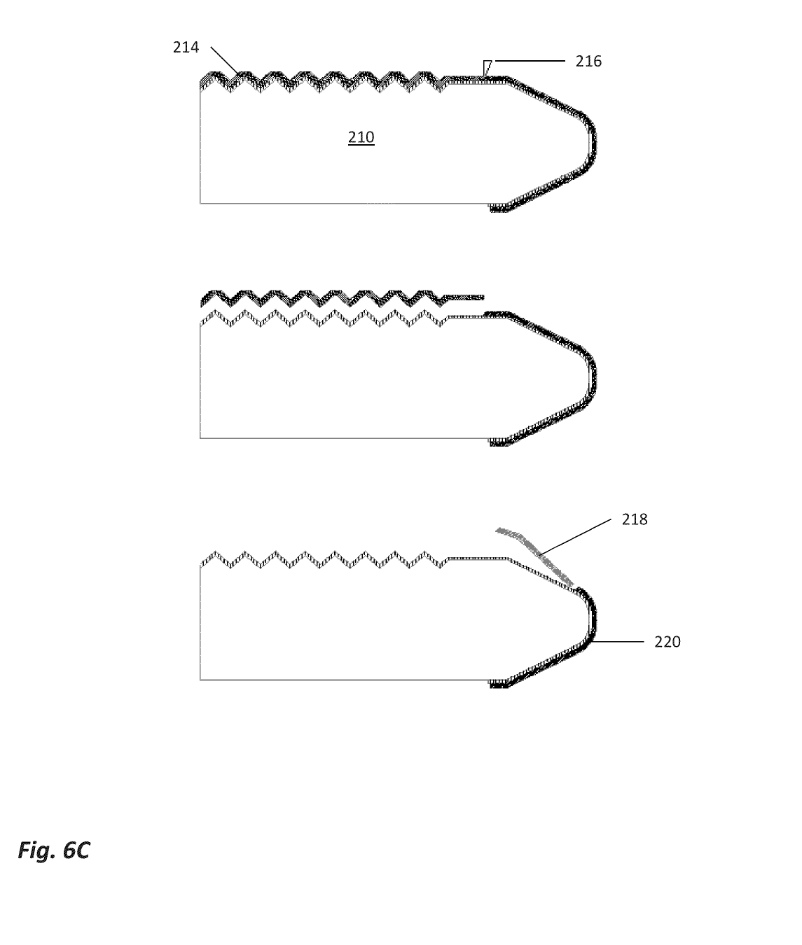

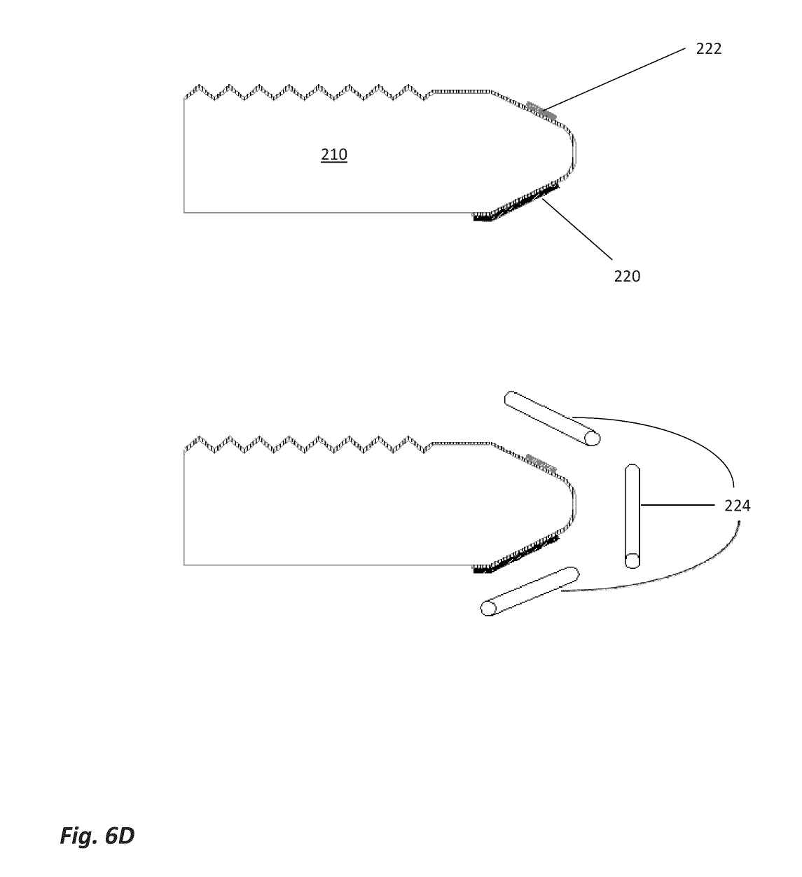

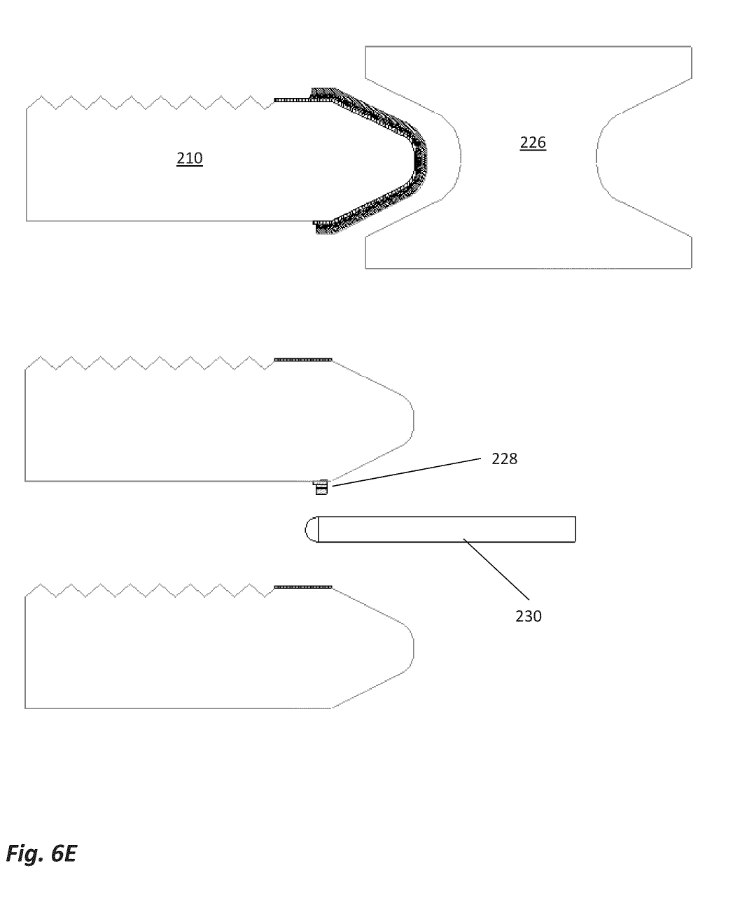

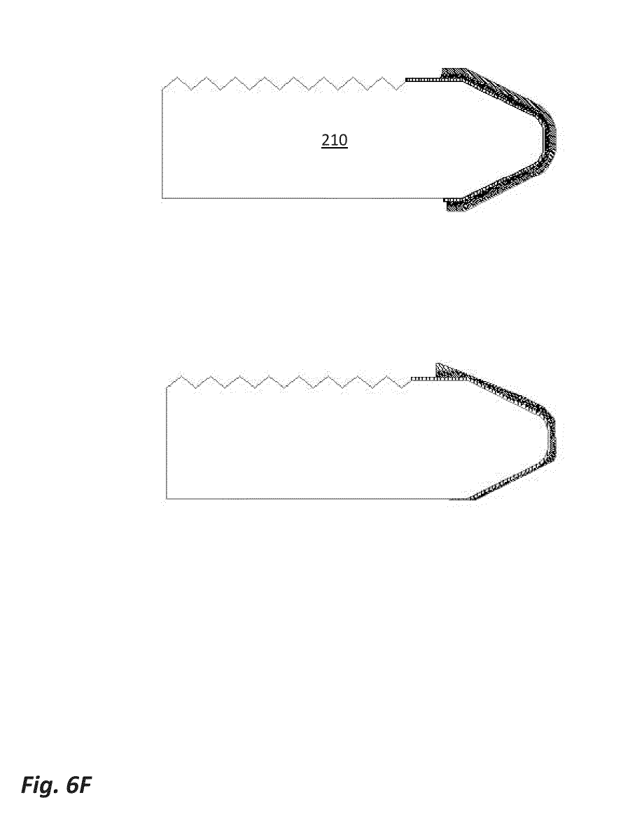

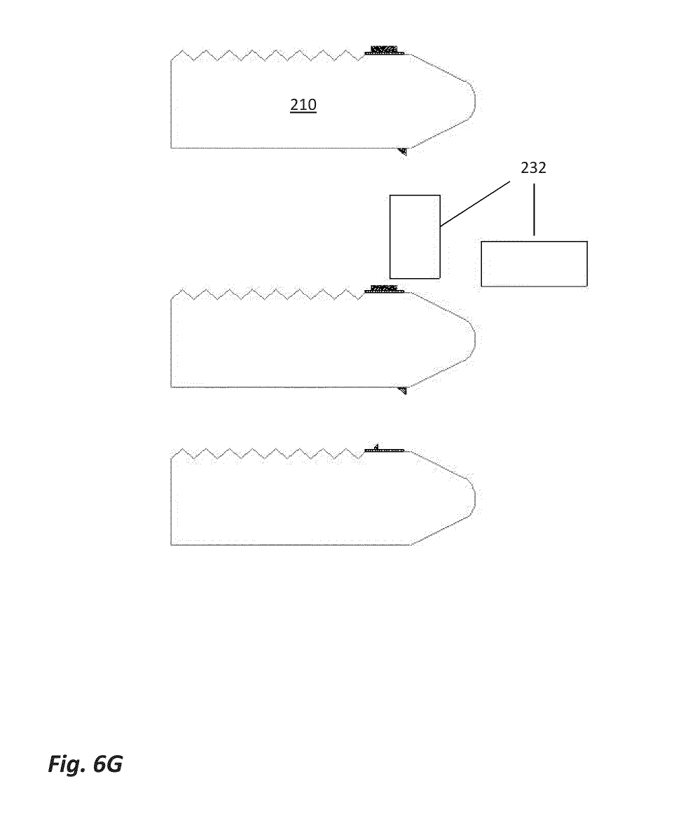

After release of the active TFSS there may be residual deposited thin film that is remaining outside of the active area, especially if the template is somewhat oversized with respect to the active TFSS. FIG. 6A shows two possibilities. Template 200 has a layer of porous semiconductor 202 which extends beyond the edge of TFSS 204. This does not present a problem for release.

However, a typical CVD deposition process can deposit material not just on the front side, but depending on the design, also on the edges and the back side of the template. The extent of the film coverage is illustrated in template 210. Thick deposition of semiconductor layer in the bevel area can be undesirable. Depending on the process, deposition on the backside can be detrimental for subsequent processing, or desired, if the backside deposition yields a comparable film to the front side deposition in the case of double side processing. Several precautions may be taken in order to wind up with a template like template 200 instead of template 210. One mode for avoiding or minimizing backside and bevel deposition is to use a neutral gas, such as hydrogen, as a purge gas in the vicinity of the edge and the backside of the template during the deposition step. Another mode for avoiding or minimizing backside and bevel deposition is to use a shadow mask that shadows the area where deposition is not desired from the deposition gas. A third mode for reducing backside and bevel deposition is to use susceptor designs with large surface area or otherwise optimized geometries which can serve to preferentially deposit material from the gas phase, thereby depleting the deposition gas in areas where deposition is not desired. Deposition processes may have preferred locations and directions where more or less material is deposited in undesirable areas. It may be advantageous to symmetrize the deposition of the undesired material across several re-uses of the same template. For that purpose, the template orientation can be tracked where needed, and dedicated changes of orientation or location can be programmed as part of a production flow.

In template 210, porous silicon layer 212 wraps partially around the edge of the template, but TFSS 214 wraps around even farther. Under circumstances where the TFSS extends beyond the edge of the porous semiconductor, other methods may be employed to remove the section of the TFSS that directly contacts the template.

FIG. 6B demonstrates TFSS release in the case of template 200. TFSS 204 is released, leaving little or no edge debris. After release, TFSS 204 may be cut to size by laser 206.

FIG. 6C shows template 210, the case where the TFSS extends beyond the edge of the porous semiconductor layer or where the porous semiconductor is not formed with porosities or thickness in the bevel region that are adequate for easy release of the TFSS. TFSS 214 is cut to size by laser 216 and then released from template 210. After release, a residual film must be subsequently removed. Section 218, which is bonded to a porous semiconductor layer and not directly to template 210, may be removed by use of compressed air, high or elevated pressure water or other suitable fluid, a taping-detaping process, by sonic (ultra- or megasonic) energy, or by a machining process such as grinding or lapping the residual film off the template. The grinding can for instance be accomplished using a grinding material that is abrasive and has a suitable hardness with respect to that of the semiconductor or by a soft material, which shears off the excess thin film deposit. The latter makes use of the fact that the bond force of the excess material is lower and governed by the weakened layer between the thin film and the template. The removal of excess thin film can also occur by suitable chemical etching. Suitable chemical etching can be selected to yield good dopant concentration or composition based selectivity between deposited film and template. It can also make use of a directed, localized etch.

The removal of the residual deposited thin film can be accomplished on a single wafer basis or in a batch mode. The removal processes described so far are designed to remove material at least in the flat part of the template outside of the active area and extending onto the bevel of the template at the bevel edge. Other methods may be used to remove the remainder 220 of the TFSS that is bonded directly to template 210 due to local lacking or imperfect quality of the porous semiconductor layer.

Independent of the precautions mentioned above, it may be advantageous to remove excess deposited material in the bevel or the backside area. This removal of excess deposited material may be carried out after each re-use cycle or after several re-use cycles and may be repeated throughout the lifetime of the template. FIG. 6D shows the use of grinding tape 224 to remove remainder 220 and local imperfection 222, and FIG. 6E shows the use of a machine tool for a grinding, polishing, or otherwise abrading device. With such a device, the excess deposited material in the bevel or backside area can be reduced or completely removed. For the case of the tape based grinder, the template may be spun in the presence of a tape, which is typically embedded with diamond or silicon carbide. For non-round template geometries, such as squares or pseudo-squares, the removal setup should be a different one, where, for instance, the template would not be spun, but moved from side to side, swiveled, or oscillated; or the tape holding/feeding mechanism may be moved, swiveled or oscillated. The removal process can be tuned to preferentially remove material in areas where more excess material has been deposited. Removal of deposited material at the different points around the bevel or backside area are accomplished by applying the tool, tape or sheet at different angles, pressures or positions towards the template. Other removal implementations for deposited material will be apparent to those with ordinary skill in the art. An alternative process to this type of mechanical removal of excess deposit from the template is the use of suitable chemistry which is applied locally with the goal of removing the excess deposit from the template.

In FIG. 6E, precision grinding wheel 226 (or a polishing wheel or slurry) is used to remove the film around the edge of template 210. However, this may leave backside residue 228, which may then be removed by, for example the use of backside grinder 230. It is also envisioned to combine the function of a bevel grinding wheel with that of an edge backside grinding wheel into one tool.

Another alternative process to the tape, sheet or precision bevel grind/polish step is the use of a laser, either direct or water-jet-guided, to remove excess deposition at the bevel and the underside of the template and reshape the bevel. The effect of a laser based bevel material removal process is shown in FIG. 6F. This method may have the advantage of allowing particularly precise dimensional control. A combination of the above methods is also likely. As shown, little or none of template 210 has been removed by the laser edge ablation employed in FIG. 6F.

In some cases, the processes described above in conjunction with FIG. 6C-6E will still leave some unwanted additional TFSS material on the front side of the template as well as the back side. In this case, as shown in FIG. 6G, grinders 232 may be used to remove that material. If this is not done, the remaining front side TFSS material may cause the next TFSS produced on template 210 to “lock” to that point, making release more difficult. By removing the excess material before reusing the template, this concern may be alleviated.

After the removal of the undesired TFSS material by whatever method, a typical flow may include re-use cleaning, which serves several purposes: first, to bring the template into a re-usable condition, capable of withstanding repeated re-uses; second, to remove remnants of the sacrificial release layer; next, to remove metallic contaminants that would be detrimental to the lifetimes of the subsequent TFSSs to be deposited on the same template; and finally, to remove detrimental remnants of any on-template processes, such as organic or metal-containing residues. Typically, after the re-use cleaning, the template is subjected again to the porous semiconductor formation process, thereby forming another sacrificial release layer. This is then again followed by the deposition of the thin film to be released. Subsequent processing continues as described above.

Residual deposition extending onto the backside of the template may be detrimental to further processing and may accumulate as the template is subjected repeatedly to the sacrificial layer formation/deposition/further processing/release/post-release treatment processing. Residual deposition on the backside can cause local stress points and unsmooth template surfaces which are detrimental to handling and which may increase the propensity of the template to break. Therefore, the avoidance (described above) or removal of backside deposited material may be advantageous. This may be carried out after each re-use cycle or after several re-use cycles and may be repeated throughout the lifetime of the template. These methods can be done either by removing material from the complete backside area or by removing only locally at the wafer edge the material deposited mainly at the edge of the backside.

The template is a highly valuable commodity in the overall process. Therefore, any process that serves to extend the potential number of deposition cycles (template reuse cycles) that the template can sustain adds substantially to the value proposition (by reducing the amortized cost of template per cell). Therefore, in the case of defective processing on the template or incomplete release or removal of the TFSS film, the template can be subjected to a reconditioning process. This reconditioning process may consist of grinding and/or polishing of the full area of the template or of only the problematic portions of the template. After successful reconditioning, the templates can be re-entered into the process loop and re-use can be resumed.

Grinding and/or polishing can be accomplished using a single side or double side grinder/polisher. The grinding/polishing process is chosen according to the necessity of surface finish. The TFSS described above which later forms the substrate for the solar cell does not rely on a mirror polished surface finish of the substrate. It is therefore important to point out that the porous semiconductor sacrificial layer can be formed on a template surface that does not have to start out as a mirror polished semiconductor surface. As it is not known beforehand at what stage an imperfect processing of the substrate occurs and as an HVM-compatible grind/polish process uses up the least amount of material from the starting template if the thickness is known, it is advantageous to inspect the templates at one stage subsequent to the release process, and sort them into thickness ranges, such that a multitude of templates can be processed in a grinder/polisher at the same time, to the same target thickness. The above sorting for thickness and for local residue from the deposition can be done concurrently with suitable equipment, such as optical, capacitive or gas back pressure based sensing.

The TFSS that was released from the template carrier and which may already have several processes applied to it while on the template can be processed further after the release. There are several possible embodiments for the TFSS and its further handling: for sufficient layer thickness, the TFSS can be self-supporting and handled through further processes as is. If the template that was used to deposit the TFSS material onto was structured to form a three-dimensional structure, such as an array of pyramids, prisms or other three-dimensional geometries, then the TFSS may be self-supporting even if the amount of deposited TFSS material is very small. This structural feature is a potential advantage of the three-dimensional template and TFSS. If the layer thickness is not sufficient for the TFSS to be self-supporting, then the TFSS can be supported during further processing via a suitable support plate, sheet or film.

An aim of the disclosed methods is to extend the useful life cycle of these templates and to lower the amortized cost of manufacturing and using these templates. This may be achieved by adding like material, herein referred to as “reconstructing material”, with like doping, or at least suitable doping, to form porous semiconductor/silicon by anodization (or anodic etch) onto these templates by means of epitaxial deposition with suitable doping level. For instance if the starting template is comprised of p+ doped silicon, the epitaxial film is also going to be in-situ-doped with a p-type dopant such as boron (p+) and the added reconstructing material will appropriately doped (p+ doped) to form the porous layer using an anodization process.

Such deposition process may be used whenever necessary or advantageous—such as once every template reuse cycle or preferably once every multiple template reuse cycles or when the template thickness is lower than a desired value, in order to add thickness and material strength.

In general, such reconstructing material may: a) prolong the useful life of a template (in terms of the useful number of template reuse cycles) that is defective or too thin; b) provide a thicker template allowing the template to offer a longer useful life cycle and providing a lower amortized template cost per cell; c) provide a smoothed surface for subsequent processing by improving/planarizing the surface of the starting wafer; and d) provide a more even template thickness range throughout the life of the template and thus minimize process variabilities that can be caused by excessively different template thicknesses, such as, but not limited to those variabilities that relate to the thermal mass of a template

As described previously, after the TFSS is released from the template then the template may be treated with further process steps, using surface etching/cleaning and other processes to enable it to repeatedly undergo this same porous silicon (PS) formation, TFSS deposition, on-template processing including the optional application or attachment of a supporting backplane, removal process, reconditioning process. During these cycles, the template loses thickness.

However, there is a practical limit to the tolerable template thickness loss and because of material thickness loss, template strength will be decreased and the rate of breakage of templates may become excessive, resulting in substantial yield losses.

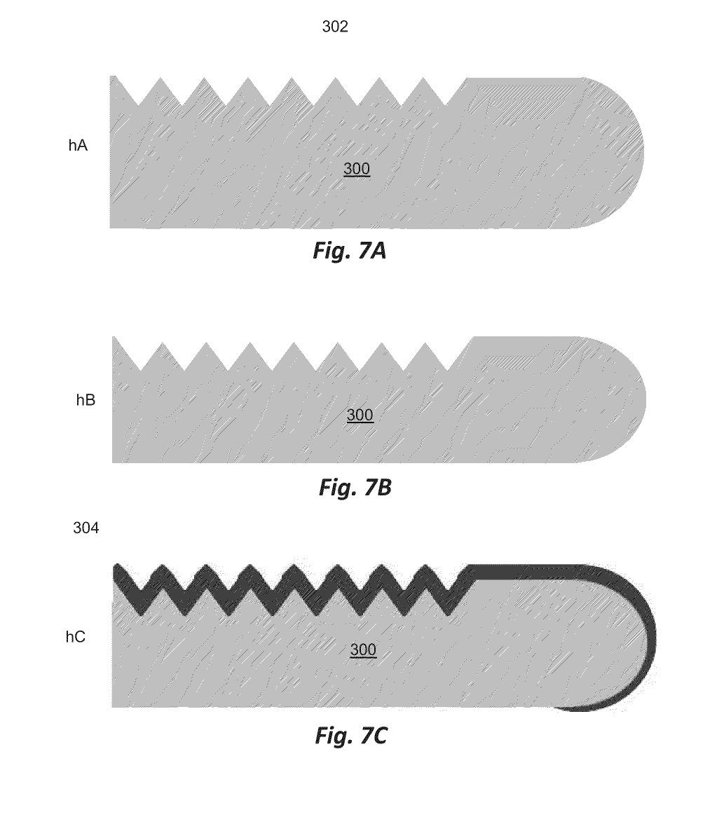

In order to avoid these disadvantages of template thickness loss, the disclosed methods extend the life of the template by thickening it up with a crystalline, preferably epitaxial or otherwise quasi-epitaxial film of like doping. A quasi-epitaxial film is hereby defined as a film that is grown on a template which itself is a quasi-monocrystalline template, such as from a silicon wafer generated from a quasi-monocrystalline ingot. This process is outlined generally in FIG. 7A-C which depict a three-dimensionally structured template as an exemplary embodiment and planar, substantially planar, and randomly pre-textured templates may also employ the same methods. As template 300 goes through TFSS fabrication processes, the thickness of the template, shown in FIG. 7A as original thickness hA, decreases to smaller thickness hB as shown in FIG. 7B. (For clarity of illustration thickness reduction is not shown to scale). Note in FIG. 7A the ridges of the three-dimensional structures, inverted pyramids 302, are on an equivalent plane with the flat front side template edge (the edge is the non-used portion of the template). However, in FIG. 7B, after the template has been thinned from anodic etching and/or wet etching the ridges of the three-dimensional structures are not an equivalent plane with the flat template edge—they are substantially lower. The thickness of the template may then be increased by epitaxially depositing like material 304 to the template which increases the template thickness, shown in FIG. 7C as hC. Shown, reconstructing semiconducting material 304 is of the same type and doping concentration as the starting template shown in FIG. 7A. Also note that the ridges of the three-dimensional structures have been restored to be on an equivalent plane with the flat template edge. Thus, the template thickness and three-dimensional structure have been recovered by the deposition of a layer of like material on the template top surface (used for the formation of PS).

Importantly, the methods provided may be applied to a template or wafer with any three-dimensional surface topography—typically a three-dimensional surface topography comprises cavities defined by ridges forming the opening of the cavities on the surface of the template.

The thickening process may be carried out multiple times during the life cycle of a template. Thereby adding a large value to the template, especially if the expitaxial deposition process on a given template can be done in a more cost-effective way than producing the starting template by wafering processes. A periodic or otherwise regular thickening of a template, for instance after a fix number of re-uses or when thickness drops below a certain threshold, is advantageous for the sustainment of a production line and for retaining tight control over processes such as thermally driven annealing, growth or deposition, printing or lithographic processes, lamination, and other processes that benefit from a smaller range of thicknesses.

As a variation, it is possible to start out with a more lightly doped template and only dope the area that undergoes the subsequent anodization cycles more highly (depicted in the figures as the top surface of the template) through the epitaxial deposition of the thickening layer. This may allow the utilization of a lower cost starting template as the price of semiconductor wafers is typically affected by the amount of dopant. Also, throughout an ingot, the doping level typically undergoes a significant profile. Thus, the impact these doping variations have on the formation of a TFSS, potentially throughout the lifecyle of the template and the formation of numerous TFSS, may be reduced by depositing reconstructing material only on the template surface layer that is to be anodized to form the porous layer. Another embodiment involves starting out with a higher doping concentration for the template and depositing a lower doping concentration at the surface. While potentially adding to template cost, such an arrangement allows for a very effective equalization of the electric field across a wafer during the anodization process which is used to form the porous semiconductor layer or layers.

Other benefits to depositing a relatively thick layer of epitaxial silicon onto the template to thicken template thickness include smoothing process imperfections which may be encountered throughout the cycles of re-uses of the template.

First, as part of the removal of the thin film (TFSS) from the template, a cutting process, using for instance, but not exclusively lasers, may be employed. This cutting process may intentionally or unintentionally due to variations generate cuts and marks on the surface of the template. These cuts may be smoothed out by subsequent etching, to provide a crystalline growth surface. The thick epi deposition for thickening is used to planarize the new starting surface—thus preventing subsequent negative impacts of the cutting marks.

Second, because in general there can be areas/regions on the template where, due to either handling, contact forces from carriers or susceptors, or due to particulate contamination, the PS anodized layer is not perfect. Then, during the baking process before epitaxial TFSS deposition the top layer does not reflow perfectly in the affected areas. This may lead to zones on the template where the perfect removal of the TFSS is no longer possible because part of the TFSS is locked to the template. Template edge areas are especially prone to such occurrences. Because the TFSS generally does not have the right doping to enable subsequent PS formation, the locked area is likely to increase, both in height and width, as surrounding areas do not get optimal current density during anodization and as silicon deposited on locked areas will itself provide holding forces that resist the removal of surrounding TFSS material.

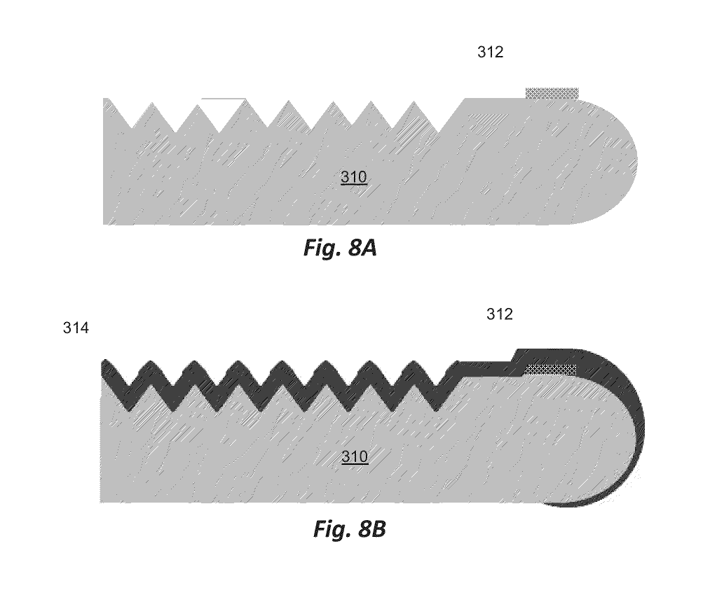

Depositing a thick epitaxial film of the right doping concentration to form PS again may render such defective spots/regions suitable for release again. This process is depicted in FIG. 8A-B in which a three-dimensionally structured template is depicted, however the same concepts apply to a substantially flat or randomly pre-textured template. FIG. 8A shows template 310, after several TFSS fabrication and re-use cycles, with residual epi layer 312. Residual epi layer 312 has the wrong doping concentration for PS formation and will become a permanent defect in the TFSS formation process as not porous semiconductor or porous silicon may be formed on this layer.

In FIG. 8B, epitaxial growth layer 314 has been formed over residual epi layer 312 as well as the rest of the template surface used for PS formation (the top surface). Epitaxial growth layer 314 has suitable doping for porous semiconductor/silicon (PS) formation and allows for the formation of PS over the entire template surface thereby mitigating the defective residual epi layer 312 and allowing for effective and clean release of the TFSS from the template.

The epitaxial deposition of the thickening layer may optionally be followed up by a treatment to the beveled edge of the template to remove the thickening layer over the beveled edge. This additional treatment may reduce the sharp facets at the edge which are a part of epitaxial growth characteristics and which can for instance be detrimental to template strength.

Such edge treatment may be carried out in multiple ways, such as edge bevel grinding/polishing via a tape or via a grinding/polishing wheel, or via a laser edge beveling process, or via chemical etching close to the template edge. These same methods, together with area grinding/polishing may also be carried out at the edge of the backside of the template in order to reduce the effect of any backside deposition at the template edge.

Monocrystalline or quasi-monocrystalline semiconductor wafer manufacturing cost is often governed by the processes associated with the manufacturing steps such as starting material cost, ingot growth—typically performed by Czochralski growth or by casting, the latter potentially as a monocrystalline-seeded quasimonocrystalline ingot—then cropping, and squaring, slicing, bevel grinding, lapping, etching and polishing of the wafer.

To use such wafers as templates for repeated semiconductor material deposition and removal/release processes cost effectively, it is necessary to keep manufacturing cost of such templates at a minimum. Because lapping, grinding and/or polishing present substantial components of cost, it is desirable to avoid these steps all together or to replace them with cheaper steps.

Further, thin film or thin foil solar cells substrates may be generated using a starting substrate that, after slicing and optional bevel grinding, receives a saw damage removal etch. However, such thin film solar cell substrates carry forth the residual template topography from the saw marks even though associated sub-surface damage is removed. Such residual topography may or may not be desirable.

As part of the deposition process for thin film semiconductor solar cell substrates, high volume, low cost epitaxial reactors have been developed. Such reactors allow for the deposition of smooth films with planarizing characteristics at low cost.

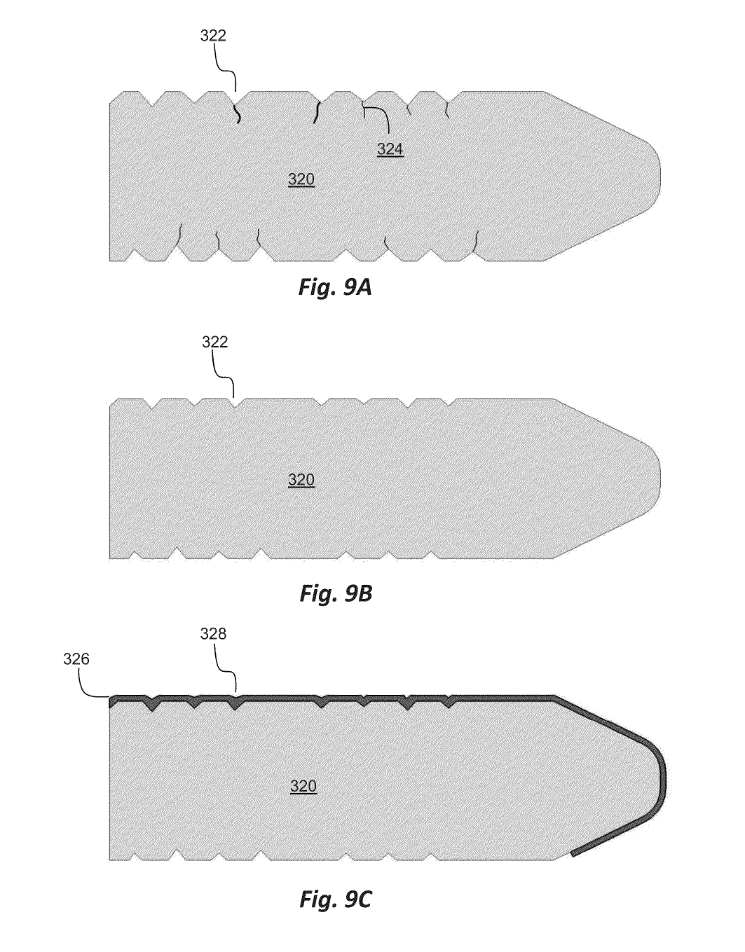

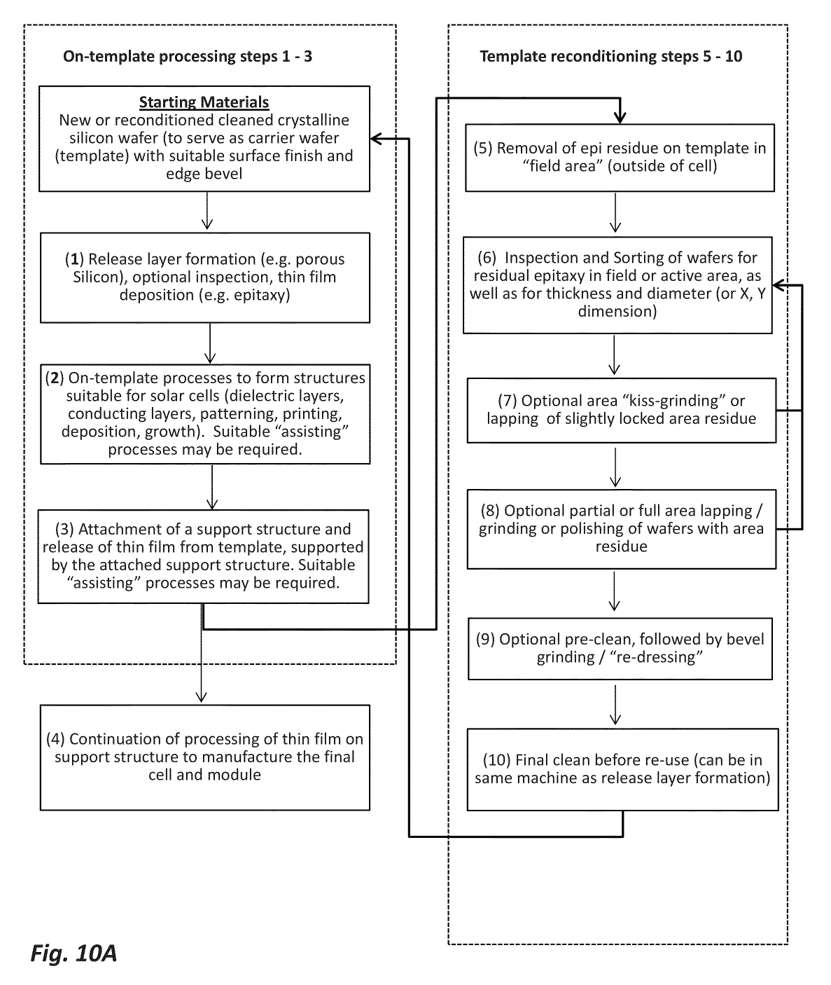

Therefore, in order to reduce the manufacturing costs of relatively smooth wafers, the process may be carried out such that as-sliced wafers, after optional bevel treatment, saw damage removal, and cleaning receive an epitaxial layer deposition with a dopant level resembling or close to the level of the starting wafer. FIG. 9A-C depict some of the key fabrication steps of this process. FIG. 9A shows wafer 320 with slicing saw marks 322 and sub-surface damage 324 created from slicing the wafer from an ingot. FIG. 9B depicts wafer 320 after a saw damage removal etch operates to remove sub-surface damage 324 but not slicing saw marks 322. FIG. 9C shows template 320 after saw damage removal etch and a front/top side epi deposition of layer 326 which has like doping as wafer 320. The planarization effect of epitaxial deposition of layer 326 provides smoothed surface topography 328 over the slicing saw marks shown in FIG. 9A-B and allows for further template processing. The wafer surface after this deposition canthen be used to form and release smooth thin film semiconductor solar cell substrates or may be processed to form a textured pattern or three-dimensional surface features. The epitaxial layer deposition is depicted on one side of a wafer. It is, however, also envisioned to perform such depositions either subsequentially or at the same time on both sides of a wafer, for instance to allow for forming porous semiconductor release layers on both sides of a wafer or template and later harvesting solar cells from both sides of the template.

As an additional benefit, unlike wafer lapping, grinding or polishing, which all consume silicon in the process and thin down the wafer, the use of a deposited film actually thickens the wafer, thereby rendering it usable for a larger number of re-use cycles.

From the aforementioned disclosures, other advantages of depositing epitaxial layers of suitable thickness and doping type and level for the formation of templates for solar cell substrate production, as well as for other fields, such as the fabrication of micro-electro-mechanical structures (MEMS) can be derived by those skilled in the art. The following description and corresponding figures, not limited to the above, relate more directly to the subject matter disclosed in the present application.

The following disclosure, as well as the above, relates more directly to the present application and pertains to the use of semiconductor wafers, such as monocrystalline silicon wafers, as re-usable carriers, also called ‘templates’, for the repeated production of deposited thin semiconductor films (such as monocrystalline silicon films) that are subsequently released from the carriers after completion of a series of processing steps on the thin semiconductor films while the thin films is still attached to, and thus supported by, the template. The released thin semiconductor film may then be further processed into devices such as solar cells or other semiconductor devices. The disclosed subject matter also pertains to processes that enable enhanced performance and yield of said thin semiconductor films and solar cells built thereof.

This disclosure provides new structures, methods and apparatuses to enable multiple re-uses of carrier wafers, such as crystalline semiconductor wafers, despite dimensional and qualitative changes of the carriers during multiple thin semiconductor film fabrication cycles and process imperfections such as residues. Further, these methods and apparatuses reduce or avoid certain process or dimensional imperfections and changes.

This disclosure also demonstrates a new structure and method for avoiding excessive semiconductor film deposition onto areas on the backside of wafers where deposition is not favorable. In addition, a method is disclosed which allows for adaptation of optimized template form factors and edge shapes throughout the usable life of said templates. Further, methods, structures and apparatuses are described which facilitate new logistics concepts within a solar cell fab that processes thin semiconductor films that are repeatedly deposited on and released from reusable carrier wafers as a fabrication basis for its solar cells. In such approach, at least some solar cell processing steps are performed on the thin semiconductor films while being supported on the carrier wafers and before they are reinforced using reinforcement plates and released from their carrier wafers. This disclosure also contains methods for suitably protecting the edges of said thin semiconductor films during subsequent processing, in order to achieve effective passivation, enable high quality passivation coatings, and prevent edge crack formation and propagation throughout the thin film and particularly the active area of the solar cell. New methods for providing a front surface field at low to moderate overall thermal budget are proposed as well.

Crystalline silicon is currently the dominant absorber material for photovoltaic solar cells. A large extent of the manufacturing cost of today's solar cells is accrued from the silicon wafer manufacturing used for fabrication of solar cells.

To that end, the use of thin silicon films, particularly thin monocrystalline silicon films with thickness in the range of a few to 10's of microns, for fabricating high efficiency solar cells is very attractive.

It may be particularly advantageous to use crystalline silicon wafers, and preferably monocrystalline silicon wafers, as carrier wafers in a thin monocrystalline silicon films fabrication process. In one embodiment, a sacrificial release layer (or separation layer, or cleavage layer) is formed on a surface of the carrier wafer and subsequently a thin crystalline layer (such as monocrystalline) or layer system of silicon and/or other semiconductor is epitaxially deposited on the sacrificial release layer. Optionally, solar cell fabrication process steps may be performed on the thin crystalline layer while it is supported on and by the carrier wafer. The thin crystalline may then be released from the carrier wafer, optionally after reinforcement with a subsequent carrier plate (which may be a permanent reinforcement plate) if desired.

Prior to release, it may be advantageous to use the underlying silicon carrier wafer (reusable template) to support the thin semiconductor film (such as the thin monocrystalline thin film on a monocrystalline carrier wafer) during a variety of processing steps, particularly those processes typically required to form a solar cell such as, for example, deposition, printing or growth of blanket or patterned isolation layers, patterning of layers, contact openings, contact material depositions, and attachment of support structures that subsequently support the thin film after release from the carrier wafer. Additional processes which allow for the above on-template processes are provided herein.

After the release of the thin semiconductor film from the carrier, and optionally onto a support structures (which may be a permanent support structures such as a solar cell backplane), additional processing may be required to complete the fabrication of the solar cell. Such post-release processes include, but are not limited to those provided herein, processes which may be performed on the released surface of the thin semiconductor film (optionally supported on the permanent support plate) such as surface texturing and passivation of the sunnyside of the solar cell.

In general, above-described structures such as crystalline (such as monocrystralline silicon) carrier wafers (such as reusable templates) and a suitable sacrificial release layer (such as porous silicon) allow for deposition of high-quality monocrystalline material as required for high efficiency solar cells. Often, in order to make this process economical, the carrier wafers (or host templates) need to be reused multiple times allowing the starting carrier wafer cost to be amortized over multiple reuses.

During the thin semiconductor film fabrication process, the carrier wafer is treated to several fabrication processes such as reuse cleaning, optional etching, sacrificial release layer or layers (such as porous silicon) formation, high-temperature epitaxial semiconductor deposition. Optionally, the carrier wafer may then also support the thin semiconductor film (such as a monocrystalline silicon layer with a thickness in the range of less than 1 micron up to approximately 100 microns, and more preferably in the range of less than 50 microns) through several process steps (for instance, most or all the process steps on the backside of the back-junction/back-contact solar cells) leading up to the release of the thin film (wherein said release may occur after permanent reinforcement of the thin semicondutctor layer using a low-cost reinforcement plate, such as a backplane). Thus, the disclosed subject matter provides an optimized and economical process allowing for the repeated use of one carrier during the fabrication steps such as those described above.

The disclosed subject matter relates to the deposition of thin film or thin foil materials in general, and more specifically to deposition of epitaxial monocrystalline or quasi-monocrystalline silicon film (epi film) for use in manufacturing of high efficiency solar cells. In operation, methods are disclosed which extend the reusable life and to reduce the amortized cost of a substrate or template used in the manufacturing process of silicon solar cells. Further, methods are disclosed which provide for the conversion of a low quality starting surface into an improved quality starting surface of a silicon wafer.

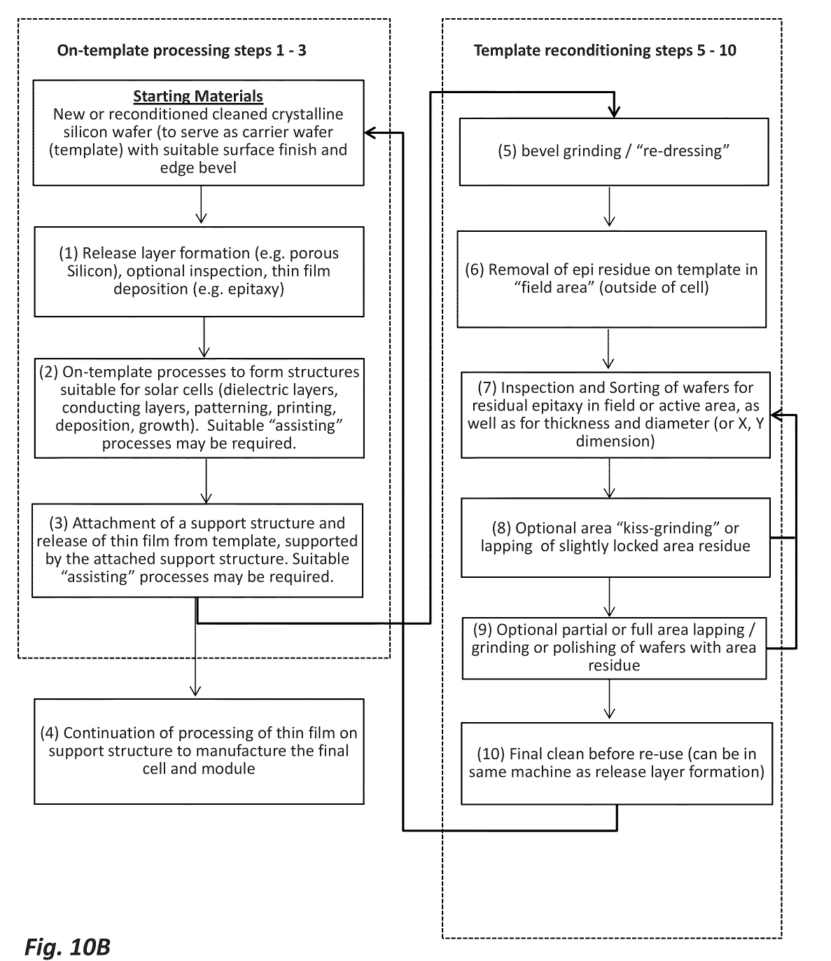

FIGS. 10A and 10B are two process flow embodiments describing the major fabrication steps for manufacturing high efficiency crystalline thin film solar cells in accordance with the disclosed subject matter, including but not limited to the back-contact/back-junction solar cells using thin monocrystalline silicon (or another semiconductor) substrates. These two exemplary process flows are disclosed for descriptive purposes only as the described steps may not all be necessary, may be amended by additional steps and refinements, or may also be employed in different sequence and on a variety of materials. Again, the disclosed subject matter disclosure may be applicable to any number variations of the described processes and materials.

The starting template for each manufacturing and cycle, whether a fresh or reconditioned template, may be semiconductor wafer (such as crystalline silicon wafer) of any shapes or dimension, such as rounds, squares, rectangles, pseudo-squares, squares with corner radius or various other corner truncations. However, it may be practical to use common starting template shapes and some processes are improved by or benefit strongly from suitable bevel shapes and dimensions and/or shapes of the templates themselves.

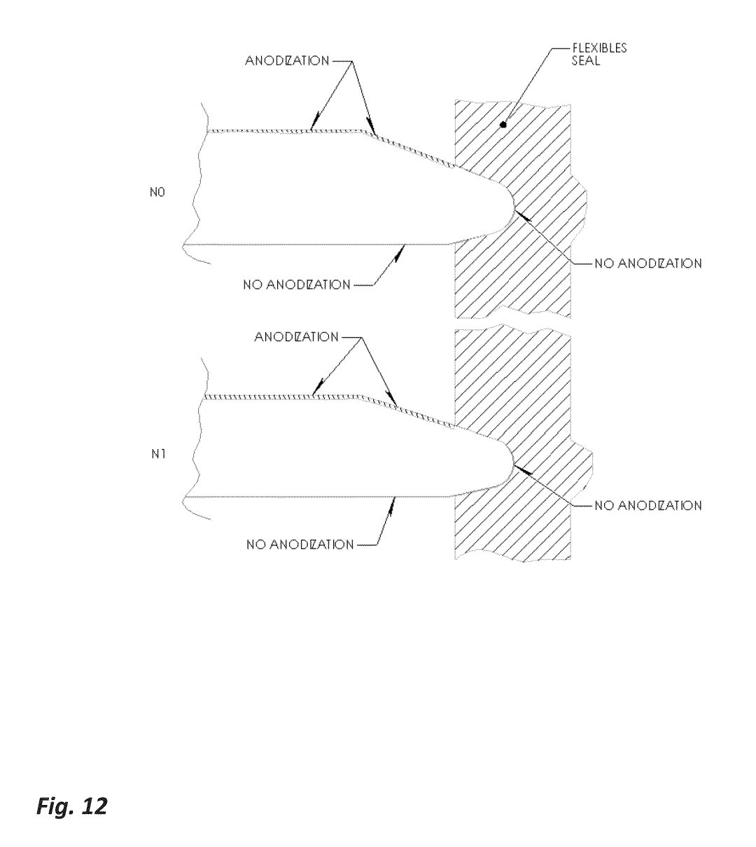

During the formation of the release layer or layers, step 1: If porous silicon (or porous semiconductor in general) is used for the release layer or as part of a layer system (for instance, porous silicon with at least two different porosities), then it may be cost effective to perform the deposition in a high-productivity batch porous silicon reactor. Detailed descriptions of suitable methods and apparatuses for porous silicon formation have been previously disclosed. For an anodization (or anodic etch) reaction, in one embodiment the electrolyte is sealed between the wafers in a multi-wafer batch by suitable edge sealing of templates. A suitable edge seal should be compliant enough to accommodate dimensional changes and small edge imperfections. As a result, at the edge of the wafer, the seal may wrap over at least a small part of the wafer (as can be seen in FIG. 12). On the “front side” or the side which is anodized (although both sides may be anodized for a two-sided template yielding solar cells from both sides), this sealing wrap may prevent local anodization near the very edge of the template. As a consequence, there is no or insufficient structure/thickness of the release layer formed close to the edge. Thus, after deposition of the thin film and subsequent release of the thin film from the template, the template surface area without suitable release layer may contain residue of the thin semiconductor film as the semiconductor thin film deposition (such as epitaxial silicon deposition) may proceed all the way to the wafer bevel apex—and possibly beyond, to the backside near the edge of the template.

A method to remove such residue, should it be necessary to remove it, is to use an abrasive method at the wafer bevel, such as a precision grinding wheel or a tape grinding/polishing process (or a combination thereof). Alternatively, a wet etching process that uses local etching close to the edges of the template may be employed. Such a wet etching process may be refined to employ suitable chemistry to enable faster etching on, for instance lightly n-doped material such as from lightly n-doped epitaxial layer residue, versus more heavily p-doped material such as material from a template that is electrochemically etched to form a porous semiconductor release layer system. For example, both alkaline etches, such as KOH or other hydroxides, and acidic etches may be applied for the local wet etching close to the edges.

It may be important to restrict the region of imperfect or missing release layer only to the wafer bevel, since for a bevel grinding/polishing method a scratching or groove formation should be restricted to the wafer bevel. An area grinding method may be, from an equipment and from an abrasive granularity point-of-view, substantially more difficult to avoid cutting into the silicon wafer.

A disclosed solution includes a template with a tailored edge bevel, especially a tailored edge bevel that is larger than those used in typical semiconductor applications. In another embodiment, the edge bevel is larger on the side that is anodized for porous semiconductor (such as porous silicon) formation. A larger edge bevel is advantageous for addressing edge sealing issues during the release layer anodization process and subsequent residue formation of epitaxial layer deposited on the bevel.

While a template may be oversized in diameter or other X or Y direction and subsequently trimmed to a slightly smaller dimension, a template oversized in the Z-direction (the template thickness) is more problematic since abrasive removal of wafer thickness can accelerate the thickness loss of the template resulting in reduced reuse life of the template. Further, abrasive removal of wafer thickness is difficult to achieve without asserting a momentum on the wafer that would tend to increase breakage.

The ultimate or total number of achievable template re-uses is strongly related to template thickness loss per re-use. Hence, it is desirable to minimize the template thickness loss per reuse cycle. Template thickness per re-use cycle is generally lost by the anodization process (porous silicon layer formation) as well as by etching steps that remove residual porous silicon, template silicon and other imperfections on the surface. Further, template thickness is lost for templates that undergo complete surface reconditioning through such means as grinding, lapping or polishing including electropolishing or chemical mechanical polishing.

A fresh or new wafer should ideally already be manufactured with a suitably large (e.g. >400 um) symmetric or asymmetric edge bevel. However, the template wafer loses thickness with each re-use, and more thickness on the side that is anodized since the anodized layer is later partially transferred onto the released thin film layer (the quasi-monocrystalline top layer which acts as a seed to the preferably epitaxial film) and is partially subsequently readily etched away in a suitable (such as dilute KOH-based etchant) wet etchant (the weak high porosity lower part of the layer) as part of the reconditioning process.

As the template wafer loses thickness asymmetrically during re-uses, the bevel shape for wafers may be optimally adjusted. For instance, in order to retain a consistently large encroachment of the bevel into the wafer (preferably around or more than 1 mm), a different bevel grinding wheel with a different bevel angle (or different angle tape grind/polish) may be applied to redress the bevel during each use. For example, as the wafer gets thinner the bevel angle becomes shallower with respect to the wafer plane.

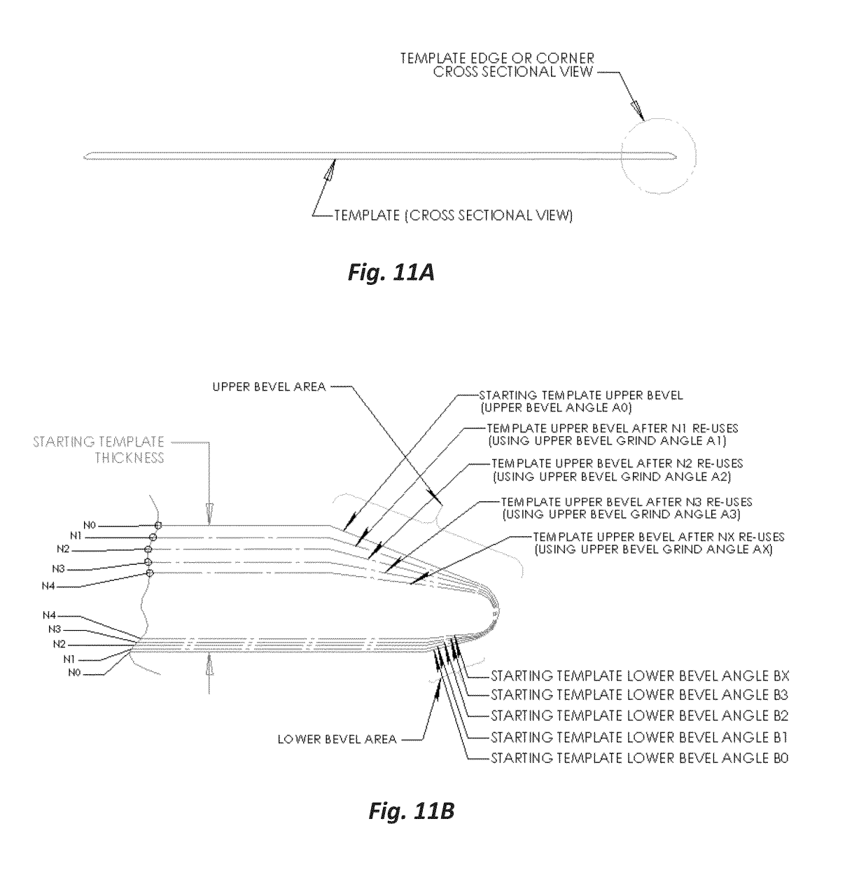

FIGS. 11A and 11B are cross sectional views of a template in accordance with the disclosed subject matter and illustrate the concept of retaining a long top side bevel for progressively re-used templates.

FIG. 12 is a cross section view of a template after multiple re-use cycles and illustrates how retaining a long top side bevel for progressively re-used templates enables consistent edge sealing of the template during anodization or wet anodic etch (typically in an HF/IPA mixture) to form porous semiconductor layer or layer structures.

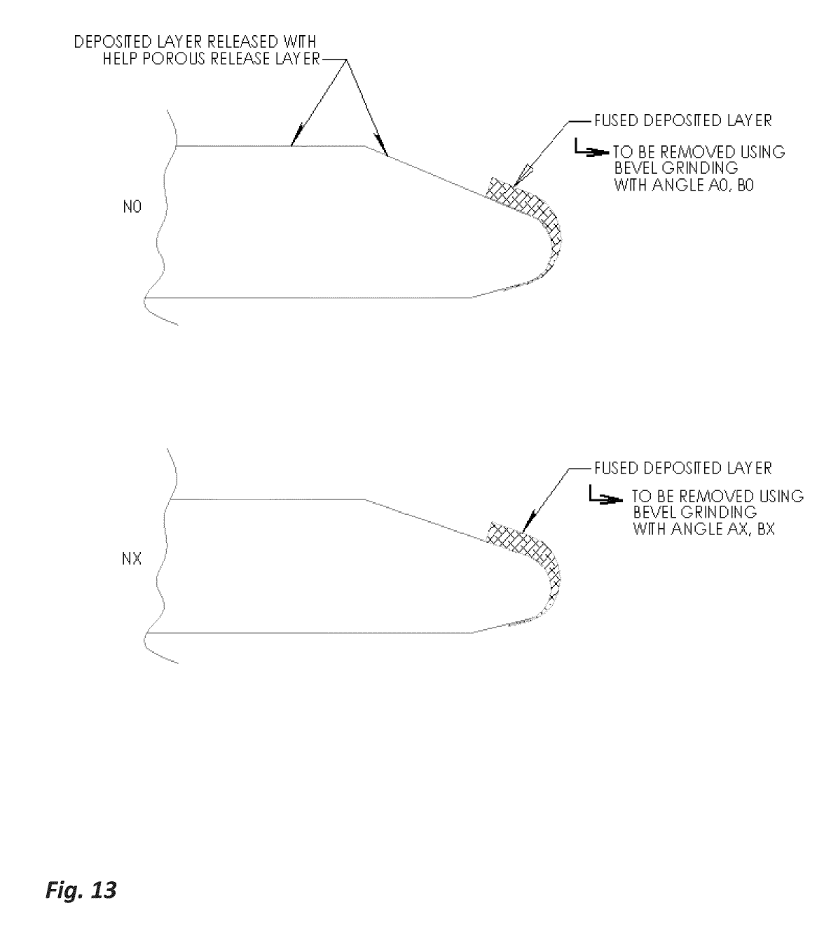

FIG. 13 is a cross section view of a template in anodization equipment and illustrates how due to the consistent edge sealing of the template during anodization using a flexible seal, the area of fused thin deposited film may be restricted to the bevel area on the template allowing for removal of the fused deposited film using a bevel grinding mechanism.

Retaining a substantially uniform electrical field for the anodization process that is used to form a porous release (and epitaxial seed) layer or layer structure for the formation of thin semiconductor film (such as a monocrystalline semiconductor like monocrystalline silicon thin film) solar substrates may be a particular challenge at the edges of the template. Thus, reliable edge sealing is important during anodization as a conductive fluid path due to leakage at the template edges may lead to non-uniform anodization. The disclosed flexible sealing solution provides a reliable and repeatable edge sealing performance for the templates and thus a reliable and repeatable anodization performance close to the template edges which allows for reliable and repeatable edge residue removal performance.

An anodization chemistry which provides for an anodization liquid conductivity that retains a uniform electric field and a uniform anodization close to the template edges may also be utilized.

Common anodization chemistries include mixtures of hydrofluoric acid (HF), water and typically an alcohol. For example, because HF acid does not dissociate completely, the conductivity of the fluid is typically limited. However, additives may be chosen in order to increase the conductivity of the anodization liquid. With increased an anodization liquid conductivity, electric field non-uniformities may be more readily equalized, including non-uniformities caused by asperities or other non-geometric uniformities often found close to the edges of the wafers where flexible seals and holding devices lead to local disturbances of the electric field. This may be particularly applicable in a batch anodization system where the distance from wafer to wafer (template to template) is often chosen to be small in order to increase anodization batch sizes for economic purposes. Increasing the electrical conductivity of the anodization liquid may also reduce the power dissipation and electrical power requirement of the batch anodic etch tool. Suitable chemistries may include salts—whose potential residues are benign to the lifetime of the thin film later deposited on the release layer or layer structure. Other chemistries may include conductivity enhancing materials without metallic components or with metallic components that are known to not form deep traps in crystalline and/or epitaxial semiconductor layers. For example hydrochloric acid (HCl) because of its large fraction of dissociation which leads to good conductivity even in moderate concentrations, as well as for its propensity to keep metals in solution rather than plating or depositing onto the surface of the porous layer. An additional benefit of adding a conductivity-enhancement additive or salt to the anodic etch bath is a reduction of the liquid bath heating due to ohmic power losses in the bath. The reduction in heat reduces electrical power consumption per wafer and increases process repeatability and control due to reduced bath heating and temperature change.

Another type of additive that may be beneficial to anodization uniformity are additives that promote the dislodging of gas bubbles from the wafer surface during anodization reaction—such additives may prevent gas bubbles from lingering close to the surface. For example hydrogen peroxide, a liquid oxidizer which can react with and reduce the hydrogen bubbles formed during the anodic etch process. The addition of a small amount of hydrogen peroxide (H2O2) to the anodic etch bath (for instance to the mixture of HF+IPA+H2O) may result in effective reduction of the hydrogen gas bubbles and better porous silicon formation uniformity. However, the disclosed solution extends to any additive which can effectively react with and reduce hydrogen bubbles without having a detrimental interaction with the anodic etch process itself.

An advantage of an asymmetric bevel in accordance with the disclosed subject matter is that the smaller radius at the back-side of the bevel helps suppress backside deposition of the thin film. Such backside deposition is typically not advantageous for subsequent vacuum chucking processes or any other processes—such as pressurized lamination or others—where a flat wafer backside is required or advantageous. Yet another solution against excess backside deposition is the grinding off of excess film deposited close to the backside bevel, which may be performed using the same bevel grinding tool that is used to redress the bevel.

Further, using flat chucks with grooves in areas where flatness would be compromised by the presence of the deposition residue—typically areas around the backside edge of the template wafers—may limit excess backside thin film deposition residue. Such edge grooves in chucks may also prevent excessive stresses in templates during chucking and thus may be beneficial to enabling a high number of re-use cycles per template.

Bevel grinding robustness and repeatability with respect to the work piece (the template) may be improved by reducing loss of any excess diameter in the X, Y, or any dimension, during the redressing of the edges. Excessive diameter or dimensional loss increases the difficulty of edge sealing during the porous silicon anodization process. To limit such loss, the templates may be presorted by thickness and/or X Y dimensions and bevel grinding tool adjusted in accordance with following to secure optimum performance in retaining bevel and template wafer dimension.

Rather than pre-sorting, thickness measurements may also be carried out on-the-fly or at least on the template's path to the grinding process station.

Further, utilizing a centering process that is robust and keeps the template wafer reliably centered around a beveling chuck or holder. This may be accomplished optically or with a suitable clamping station, for instance with symmetric force/spring force application as is known in the industry.

Other embodiments include using a reference point for the grinding wheel (tool) with respect to the chuck that holds the substrate. Measuring the dimensions of the template before the grinding process and using this information for centering, especially in conjunction with a mechanical reference or with an optical reference from fewer than all sides of the template. Having a mechanical or non-mechanical stop or reference for the grinding wheel with respect to the chuck that holds the substrate. This mechanical or non-mechanical stop or reference can be, but is not limited to a non-contact stop using optical means or air pressure as a sensed reference or directly for centering. Alternatively or in addition, using the same trajectory of tool and/or template wafer to be grinded each time for a template wafer of a certain sorting bin.

In accordance with the disclosed subject matter and by using pre-selection, and appropriate binning and batching of template wafers, the bevel grinding of the wafers may be processed in parallel—in other words, the wafers may be batch bevel grinded. For parallel processed bevel grinding, the wafers may be stacked (optionally with distancing plates between them), aligned (optionally all at the same time), then secured (for instance by vertical pressure), then bevel grinded using one or more wheels at the same time. This may be accomplished on all sides of the wafer all at once or with a re-chucking/reorientation of tool or the template wafer stack. Grinding dimensions, such as those pointed out above, in order to closely retain the X/Y dimensions of the template wafer are also applicable for parallel processing. Other modes of parallel processing may include the use of parallel positions that share at least one or more of the control axes of a precision machine tool used for the abrasive machining operation. Such control axes may include the template holder table or pallet as well as the machining tool spindle holder.

In parallel process embodiment may use a movable centering device that can reference each template to its process station. Such a centering device may, for example, be mounted on a robotic device that can then be moved from process station to process station.

In another embodiment, a separate alignment station location and a separate process station are used where both are situated on pallets that may be moved or swapped so that grinding process of the current templates and centering process for the next set of templates occur in parallel.

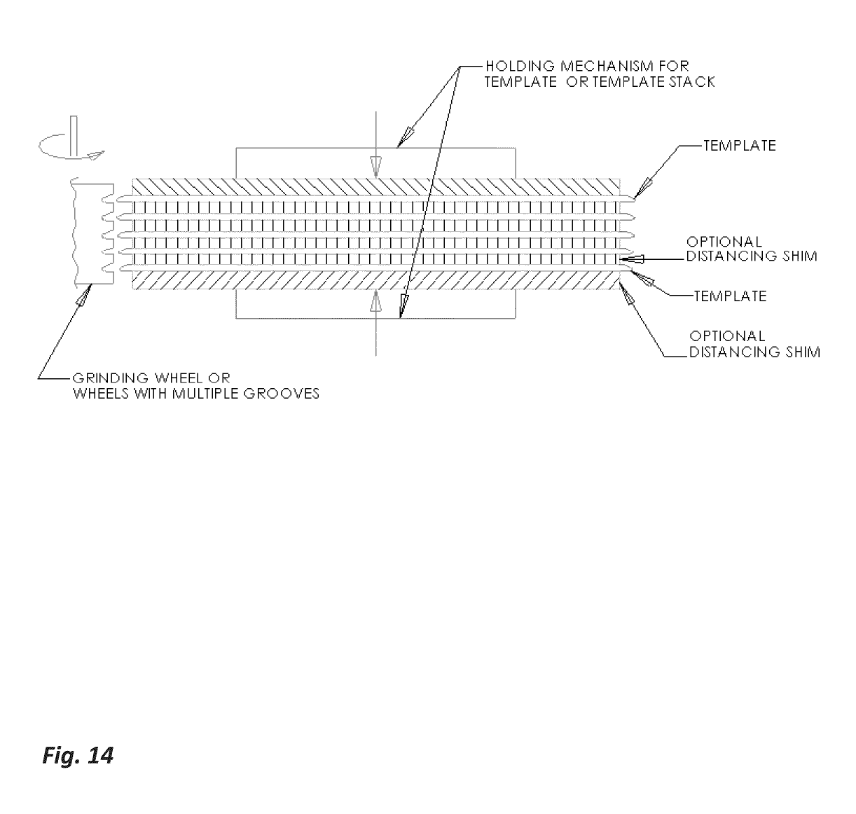

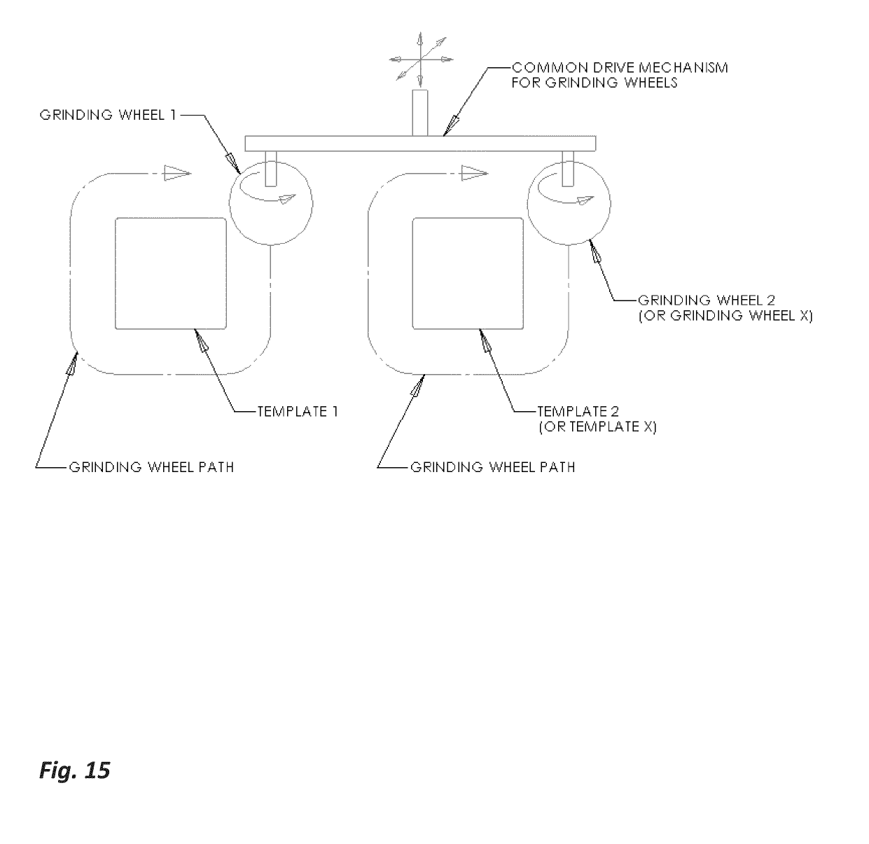

FIGS. 14 and 15 are diagrams of two parallel bevel grinding embodiments in accordance with the disclosed subject matter. FIG. 14 shows a vertical template stacking embodiment for parallel edge grinding and FIG. 15 shows a side by side, or at least a separately held, parallel edge grinding embodiment which utilizes at least one of the axes of the machining equipment jointly for more than one template. Additional parallel processing designs may be further derived by those skilled in the art. In one embodiment, the centering of the template on the processing chuck prior to processing is achieved while other templates are processed.

Further, a grinding machine may also be used to remove stubborn residue of the thin semiconductor (such as thin silicon) film on the top surface of the template wafer, especially close to the edge. This process may be used to remove or reduce residue in areas where the porous semiconductor or silicon release layer structure is too thin or has insufficient porosity to allow for full release but is still conducive to being sheared off by an abrasive wheel which does not cause abrasive action on the template surface layer itself. For example, this may be carried out using a separate wheel from the edge grinding wheel or a separate portion of the same wheel tool. Further, similar parallel modes of operation for the edge grinding process can be implemented.

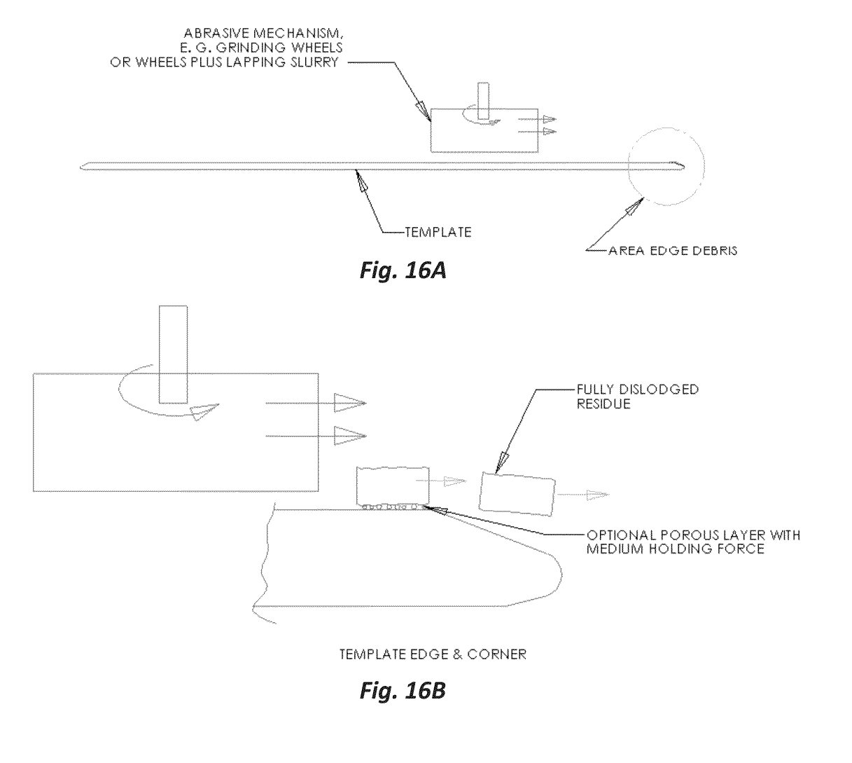

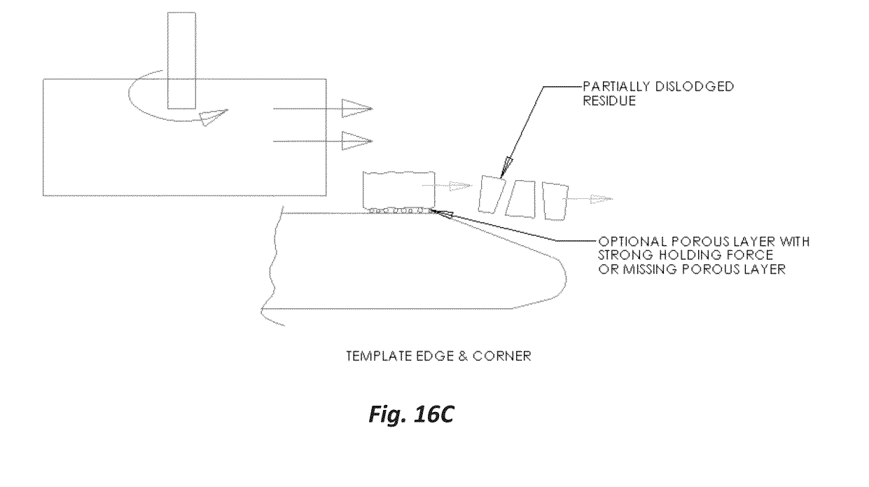

FIG. 16A is a diagram of a device for applying a medium residue holding force where the abrasive or mechanical removal mechanism is sufficient to remove the residue down to the porous layer. FIG. 16B is a diagram showing an expanded view of the abrasive effect of a device FIG. 16A. FIG. 16C is a diagram showing an expanded view of the abrasive effect of a device such as that shown in FIG. 16A for a stronger holding force of the residue. The abrasive or mechanical reduction of residue height is beneficial for further processing, by reducing asperities at the wafer edge that can otherwise prevent proper sealing in the anodization bath.

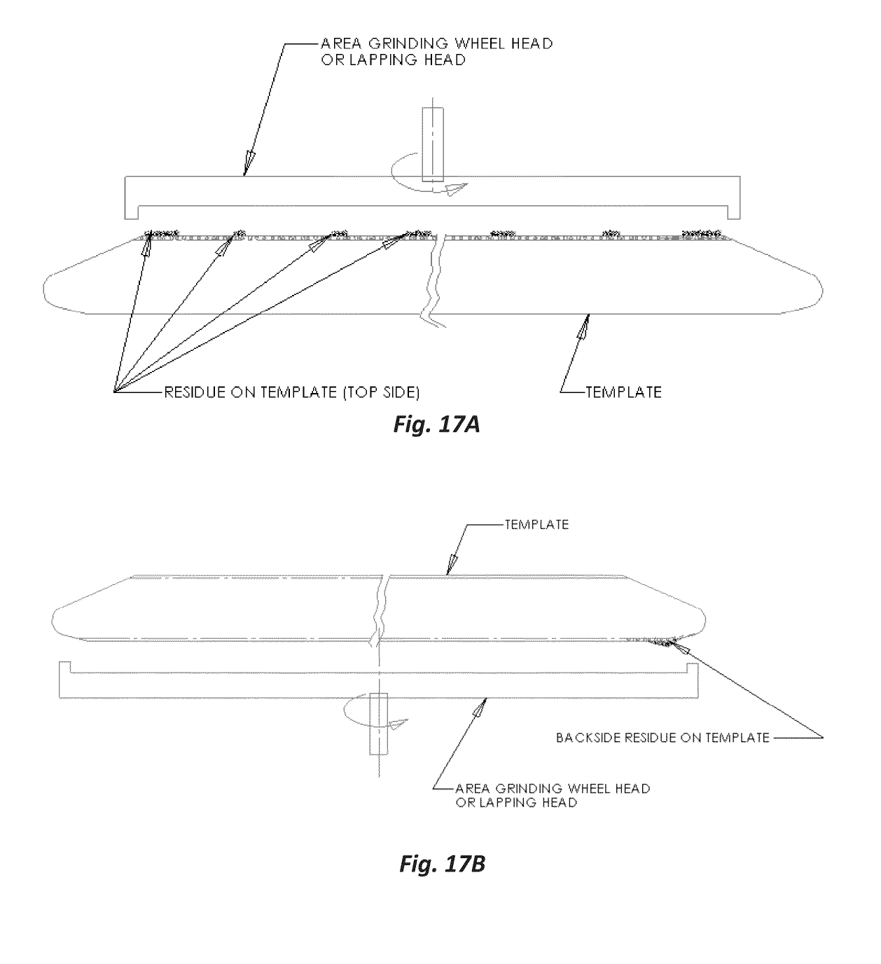

FIGS. 17A and 17B are diagrams showing a device for removing residue with a strong holding force, for front side as seen in FIG. 17A and back side residue as seen in FIG. 17B. Areas on the template having a residue with a strong holding force, possibly due to larger imperfections the deposited thin film, which cannot be removed using the above “kiss-grind” removal require a more substantial surface reconditioning, such as area lapping, grinding, polishing or a combination thereof. In the same fashion, excess backside deposited thin film can be removed from the backside by an abrasive process.

Determination of the processing need for the reconditioning path may use an optical or capacitive detection technique that determines the extent of residue. Depending on the nature, amount and location of residue found on template wafers, the wafers are sorted for different reconditioning routes—such as light, medium, or heavy residue. Appropriate processes are then selected and employed to recondition the complete template surface or only the areas affected by excessive residue (such as the edge and/or corner regions).

The template re-use etch and cleaning steps also may be carried out in several tool configurations. These etching and cleaning processes typically have several functions such as: to remove organic contaminants, to remove metallic contaminants, to remove particulate residue, to remove or clean areas on the wafer that may be detrimental for further re-use.

The restrictions for such etching and cleaning processes are governed by processing costs as well as excessive template thickness and X/Y dimension reduction during etches. The latter may have a negative impact on the amount of obtainable re-use cycles for the template.

When advantageous or required, the re-use etch and cleaning steps may be performed on only one side of the template. For example, performing a relatively deep silicon etch on one side of the template, for instance the side where a silicon etch is used to smooth out the impact of laser or mechanical cutting into the template.

Chemistry for the template re-use clean may be selective between metallic, organic removal and silicon removal (hence, minimizing silicon removal while removing the contaminants). Thus, metal complexers may be added in the cleaning and etch chemistries to free up all metallic cations from the wafer surface to the chemical processing baths. For example, Cu, Fe and Zn are often the metallic contaminants from silicon ingots, template wafering process and template fabrication prior to reuse. Metal contamination may come from the exchange of the surface atoms to the inherent metallic impurity ions present in the reuse cleaning chemical reagents.

Silicon removal etching typically targets and results in reducing the thickness of the template wafer. For any silicon removal etch (single or double sided), the majority of the silicon may be removed prior to the edge bevel grinding. By doing so, the residual thin film on the apex of the bevel serves to prevent excessive X/Y dimension loss of the template wafer.

After bevel grinding, a potential additional silicon etch, likely at substantially smaller removal quantity, may be used for a clean-up etch. Precleaning is critical to the reuseability of the wafer templates due to the inherent organic and metal contamination which are physically adsorbed on the surface during the bevel grinding process. The addition of complexing agents in the precleaning bath, and also even in the rinsing baths, are advantageous to further sequester any metals that may likely be a source of detrimental trace metallic contamination in the process.

After (or during) silicon removal, metallic contaminants may be removed prior to bringing the wafers back to the anodization process for another re-use cycle. Routine monitoring, using for example the Vapor Phase Decomposition (VPD) analytical technique, may be performed in this process to verify the surface cleanliness. A total of thirty one elemental impurities are analyzed, and to improve the range and surface detection limits an inductively coupled plasma mass spectrometer is used to bring the surface metal concentration to as low as 1×10̂9 atoms/cm̂2. A very low trace metal concentration at the wafer surface may be due to the combination of using a semiconductor grade to an analytical reagent chemical and complexing agent. Solution temperature and concentration of the cleaning chemistry may also be significant factors.

At any point in the life cycle of a template wafer, it may be needed to change the side that the thin semiconductor film (such as the active solar cell layer) is deposited on. To do so, it may or may not be advised or necessary to redress or regrind the bevel and treat the surfaces with an abrasive process prior to again commissioning the template wafer to the re-use cycling. Criteria changing the active side of the template include excessive traces of laser cuts or pitting, scratching or other surface imperfections that render one surface advantageous over the other.

Moreover, both sides of the template may be used concurrently to form sacrificial release layers of porous semiconductor and thin semiconductor films in order to double the productivity of the template in terms of thin semiconductor film formation and harvesting of the full template area on both sides.

Often, typical current solar cell fabrications do not mark the individual solar cells with identification numbers or alignment marks, largely due to cost concerns of the marking process, which makes traceability of wafers through the fabrication line very difficult.

However, in a re-use cycle, each template wafer may be marked as the marking cost is amortized over the many re-uses of one template. Such marking allows for traceability. A template may be marked via global or local software (e.g. per production line or per equipment or per equipment type) with respect to its re-use cycle number. Information and markings may also be associated to solar cells manufactured from these templates as long as they experience on-template processing. In addition, re-use counting may be used template binning purposes for subsequent process steps as the re-use count can be associated with template wafer dimensions (such as thickness). Template thickness and dimension information is valuable in processes such as bevel or area grinding or lapping, anodization, lamination, etc.

When necessary template markings may be reapplied if subsequent re-use processes render identification marks as not sufficiently legible. Thus, a single sided silicon removal etch such as that described herein where silicon is mainly removed from the top side of the template wafer may support the retention of such template markings.

Template marking, especially on the back side, can be used for identification, but also for alignment or orientation. Therefore, other types of marking for template wafers, such as fiducials, may be used for processes that require alignment (such as laser processing, screen printing, etc.). For instance, if templates are marked with fiducials on the backside, then tool throughput improvements may be achieved by putting alignment capability, such as cameras, through the backside of wafer holders or chucks. This also provides viable and fast orientation help where alignment targets would not be immediately visible or are buried underneath non-transparent layers (particularly for any printing tools, lithography tools or laser tools).

As disclosed, templates may be sort and binned for processing according to template thickness and deposited residue. The location in the flow where sorting and binning is carried out may depend on the use and extent of wafer identification marking. In a simple implementation, wafers are sorted and binned into batches according to dimensions (X/Y and/or thickness) prior to bevel grinding allowing a determination of a suitable grinding wheel tool to be used for the whole batch.

Edge engineering and edge protection of thin film layers during processing after the removal from the template wafer also may improve and increase the number of re-use cycles for a carrier wafer. When removing the thin semiconductor film (such as the thin monocrystalline silicon film from a monocrystalline silicon template through separation at a porous silicon release layer) from the template carrier wafer, it may be advantageous or necessary to attach a support layer or layer structure (backplane) to the thin semiconductor film after completion of key on-template process steps on the exposed thin semiconductor film surface (such as completion of all the key process steps to form the emitter junction, base window, backside passivation, emitter and base contacts, and on-cell metallization for a back-junction/back-contact solar cell) and prior to its release from the template wafer.

Prior to lamination or prior to release, a laser or other mechanically abrasive tool may be used to outline a peripheral area on the thin semiconductor film larger than the final active solar cell area, but close to the area-to-be-released by performing a partial laser or abrasive cut. This cut generates a weak area and with it a preferred breaking spot within the thin film, but outside of the active area, during or prior to the release process. In order to reduce the impact of cutting into the underlying template and therefore leaving traces of the laser cut on the template-to-be-reduced, a combination of shallow cuts with extended mechanical or thermal force (such as through differential heating or cooling of template versus the backplane reinforced film-to-be-released) may be used, or the laser cutting depth can be tuned to the thickness of the deposited layer, thus adjusting cutting depth even during the laser scribe around the perimeter of the area to be released for known non-uniformities of said deposited layer and thus minimizing impact of inadvertent cutting into the resusable template, or the employment of thermal laser separation—a process that has been introduced for semiconductor dicing—may be used, namely the local heating of an area to be cleaved using a laser such as a pulsed or CW IR or CO2 laser followed by a local coolant such as water mist or helium. A cleaving technique, such as that disclosed for silicon wafer dicing in U.S. Pat. No. 8,110,777 by Zuehlke, may be used.

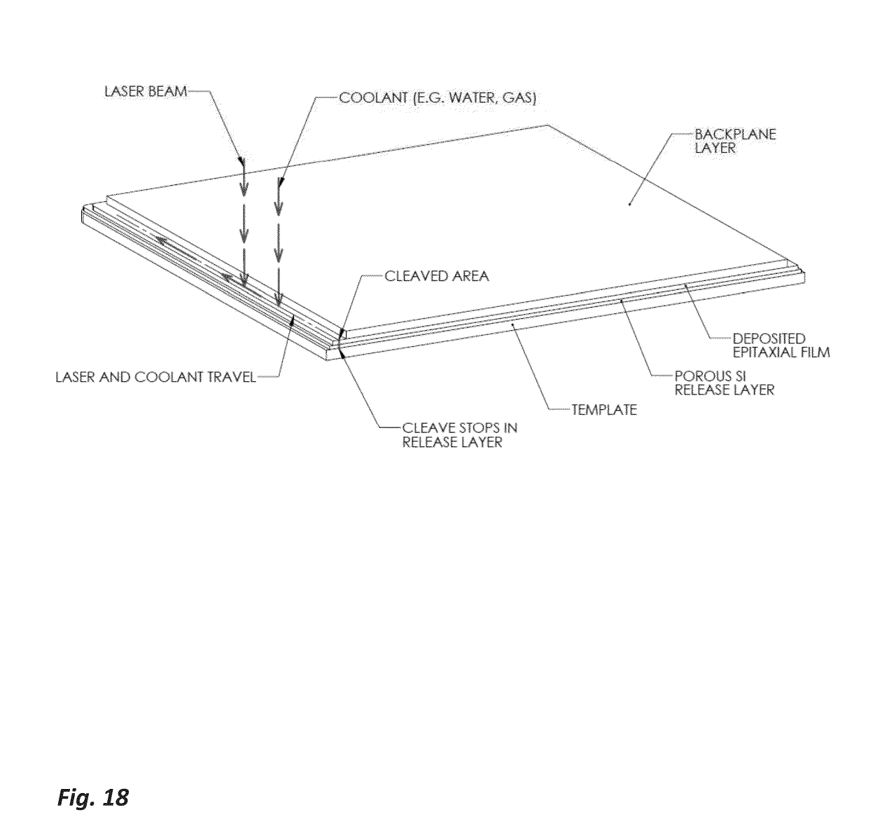

In the present application, the application of such a cleaving technique to cleave through the silicon or other semiconductor film on a wafer where the silicon or semiconductor film is separated from the starting growth wafer, called template, by a release layer or layer system, such as, but not limited to porous silicon. This disclosure provides this application of the cleaving technique also with the effect of stopping the ensuing cleave at the release layer, which, by nature of its mechanically weak structure, can serve to terminate propagation of the cleave into the underlying semiconductor template. The termination is also aided by the release layer serving as a thermal conduction barrier as well. FIG. 18 is a diagram illustrating a thermally induced cleave stopped on the release layer.

After the release of the backplane-reinforced thin semiconductor film (such as a backplane-laminated/reinforced thin film monocrystalline silicon solar cell), the final active area of the thin semiconductor film may be decoupled by laser cutting or other low damage impact cutting in order to prevent crack propagation from the edge through the active area of the device. This can be done, for instance, by using a pulsed picosecond or pulsed nanosecond laser beam to create a narrow semiconductor frame around the main active area of the cell (by forming an all-around trench penetrating the entire thickness of the semiconductor thin film and stopping on the backplane support using a laser). The laser trenching may be formed by a laser ablation process (preferably but not necessarily a pulsed picosecond or nanosecond laser ablation process for minimal edge damage and no heat-affected zone) performing the frame boundary ablation on the released side (which will ultimately be the sunnyside of the back-contact/back-junction solar cell) of the backplane-laminated thin semiconductor film. The laser-formed (or mechanically formed) trench boundary will surround the main active area of the solar cell and separates the main solar cell area from a narrow-width peripheral thin semiconductor frame. The above laser trenching process on the sunnyside of the cell may be performed either immediately after releasing the backplane-laminated thin semiconductor film from the template or subsequently after completion of the texture etch process (before or after deposition of the final frontside passivation and anti-reflection coating layer). Either at the same time as the above described inner boundary cut or subsequently after further processes such as texturing and cleaning, the edge of the oversized backplane-reinforced structure may be trimmed, potentially cutting through the thin film as well as through part or all of the backplane to define a first outline dimension.

This approach will result in a slightly oversized backplane-laminated structure (such as a back-contact/back-junction solar cell) with a narrow passive thin semiconductor frame surrounding the main active semiconductor area. For instance, a representative structure for a back-contact/back-junction backplane-laminated thin film solar cell may include a square-shaped 156 mm×156 mm active thin film solar cell area (for example comprising thin monocrystalline silicon solar cell with silicon thickness of less than 50 microns), such active area surrounded by a square-shaped peripheral trench penetrating through part of or the entire depth of the thin semiconductor film (thus, the trench depth would be substantially shallower or the same as the thickness of the semiconductor film supported by the backplane, in any case shallower than the total thickness of semiconductor film plus backplane), and the width of the trench being in the range of a few microns to over 100 microns. The width of the passive thin semiconductor frame surrounding the laser-formed trench may be in the range of 10's of microns to 100's of microns. The peripheral frame will protect the inner active cell area by preventing propagation of microcracks from the edge to the main cell area, enabling more robust handling and processing and packaging of such cells.

This cutting may be performed using a suitable cutting tool such as, but not limited to: a) one laser or several lasers to best address the different materials in the backplane/thin film solar substrate compound; b) a suitable stamping die or dies; c) one or several shear cutting arrangements; d) dicing saws that are capable of dicing through compound materials; e) any combination of the above mentioned materials. Long lasting cutting surfaces for the mechanical methods for such compound materials are silicon carbide and diamond coated tools.

This first outline dimension may be chosen to be slightly oversized compared to the final solar cell product allowing the reinforced thin film to be handled throughout several post-processing steps, including texturing, cleaning, passivation and anti reflective coatings such as silicon nitride or others, and further backplane processing such as metallization related steps.

Towards the end of the cell manufacturing process process (for instance, before test and sort), the cell may then optionally be trimmed again to its final size (preferably leaving the narrow thin silicon frame around the main active cell area or alternatively removing the frame as well) if this is not done using the first above described outside cut. prior to being assembled into the multi-cell photovoltaic module.

Oversizing supports the edge of the fragile thin film during handling, thus decoupling the very edge from the active area. It also serves as a region for holding the cell for passivation or other film deposition, avoiding optically disturbing non-uniformity in anti-reflective layer thickness. Also, it allows for deposition of a passivation layer all the way around the edge and on the sidewall of the thin film thus enabling good sidewall passivation and low recombination velocity in the edge area as well as the surface area.

Note that the sequence of cuts and the necessity of each cut may be determined by the overall process flow, as well as the holding force, built-in stresses of the reinforced thin film layer structure. This disclosure is intended to allow for implementation of any variety of such processes for optimum performance and cost.

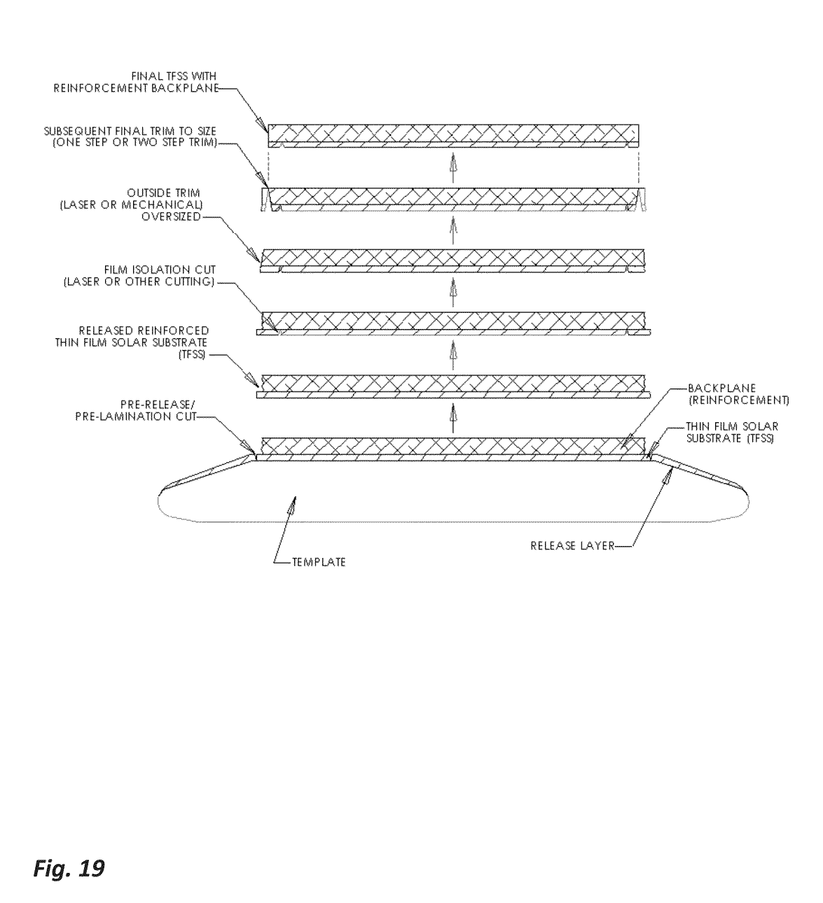

FIG. 19 is a process flow illustrating an embodiment of a structure for solar cell thin semiconductor film edge trimming. Additional process flows, including but not limited to such flows that omit certain cuts or trims, or change the sequence of cutting steps may be envisioned from these concepts by anyone skilled in the art.

High temperature bake and epitaxial deposition methods for increased template lifetime and large area release capability are also provided. The formation of high efficiency capable solar cell absorber layers (such as thin film solar substrates) are provided by way of applying a high temperature during the reflow of the porous release layer system and prior to epitaxial layer deposition, specifically template wafer temperatures above 1020° deg C. and between 1020° and 1250° deg C. This in conjunction with the use of high temperature atmospheric-pressure epitaxial deposition using trichlorosilane as the silicon containing gas in conjunction with hydrogen carrier and reduction gas may lead to significant cell fabrication improvements and template efficiency. Further, the epitaxial deposition may operate in the template wafer temperature range of 1020° to 1250° deg C. In conjunction with a well-controlled anodization process and equipment for the formation of the porous layer system, this method may be employed for the high-productivity formation of substantially uniform high quality epitaxial silicon layers at high deposition rate with high lifetime and at low cost. Further, the disclosed method may enable the release of large area (at least 100 mm×100 mm in area) cell substrates, where large area is considered to be a size equal to or above 100 cm2.

This method solves problems using known methods relating to the combination of porous silicon, epitaxial growth at lower temperatures and subsequent release, where a large area release may not be performed using a combination of porous silicon and high-temperature silicon epitaxy reliably enough to be efficiently utilized in high volume production due to insufficient thermal budget for sealing of the porous layer. For throughput reasons it may be advantageous to bake the porous silicon release layer at a higher temperature than is employed for the deposition, thereby accelerating the release layer surface reconstruction to form the epitaxial seed layer. A fast acting lamp heated batch epitaxial reactor may be suited for such a process flow.

Large area high quality releasable layers may also be achievable on lower surface quality substrates (reusable templates) with similar process conditions, thereby eliminating the need of mirror polished starting substrates, hence, reducing the amortized cost of the reusable templates. Example surfaces are those that are obtained from a lapping-etching sequence or even from an as-sawn surface with a subsequent saw damage removal etch sequence. Starting and reconditioned surfaces mau be achieved using silicon etching chemistries that are either alkaline in nature (such as KOH and other hydroxides) or acidic, such as mixes of hydrofluoric acid with nitric acid with optional additives such as acetic or phosphoric acid. These acidic etches may be followed by a comparatively mild alkaline etch surface cleanup step. The acidic etched surfaces do not provide clear crystallographically directions, while alkaline etched surfaces do provide such directions. Thus, the epitaxial growth characteristics for both surfaces are different.

Further, susceptors that are capable of withstanding high temperature deposition are provided herein. There is only a limited selection of materials that may be used as susceptors that are able to withstand the high temperatures required for optimum deposition. For example, these materials include, but are not limited to, silicon carbide coated graphite and monolithic silicon carbide.

However, cast silicon may also be used for susceptors partially due to the advent of large multicrystalline silicon ingots that have opened the possibility to manufacture large area susceptors made from silicon. These cast silicon susceptors may sustain more depositions before flaking of deposited film becomes an issue. Another advantage of using cast silicon susceptors is the straightforward/simplified wet clean or dry cleaning, as well as an ultimate re-use of the material by using it as feedstock for a recasting. Independent of the susceptor material choice, dry cleaning may be accomplished in situ using HCl (or chlorine gas) or ex situ (HCL or chlorine gas) in a low cost reactor that is focused on susceptor etching only by using HCl, chlorine or other suitable gases.

Thin film solar cells with front surface field and with optional low thermal budget anneals are also provided herein. Solar cells may benefit from front surface fields with improved front surface passivation and reduced front surface recombination velocity. When chosen correctly, such front surface fields will help improve the open circuit voltage of the device as well as the short circuit currents. Thinner cells tend to have higher sensitivity to the front surface quality.

An in-situ front-surface field with higher back surface doping is also provided herein. With a thin cell where the active absorber layer is deposited on a high temperature capable carrier and subsequently released, it is possible to have a front surface field built in as part of the absorber layer deposition, for example by epitaxial growth. This front surface field may be dimensioned such that after release and subsequent processing such as texturing, the front-most part (sunny side) of the active absorber layer still retains a higher doping than the next layer substantively closer to the emitter. In addition, it may be advantageous to have a higher back surface doping area which can serve to reduce the depletion region widths around the contact that are located close to the back surface.

For a high volume CVD or epitaxial CVD reactor, to support high gas utilization it may be advantageous to deplete the precursor silicon containing gas, such as trichlorosilane, dichlorosilane, monochlorosilane, silicon tetrachloride, silane or disilane. As this effect is typically associated with a deposition rate reduction away from the gas source, it may be advantageous to enable gas switching such that the gas flow direction may be reversed within a process and thus enable compensation of the deposition rate reduction. As a result, a rather uniform layer thickness is achieved across several wafers within each susceptor. When the cell design architecture requires regions with different doping levels, such as that described above for having front surface or back surface equipped with different doping, then the switching of the gas direction may be repeated, if needed several times.

One embodiment of such a switching, for instance, in a three region architecture may be described as follows: deposit region 1 flowing in direction A, switch, deposit region 1 and region 2 flowing in direction opposite of A, switch, deposit region 2 and region 3 flowing in direction A, switch, deposit region 3 flowing in direction opposite of A.

Options for engineering an ex-situ front surface field are also provided. For a reinforced thin cell, the material of the reinforcement, as well as potentially other materials such as existing metal lines or adhesives, may substantially reduce the available thermal budget for a front surface field process. The following disclosed embodiments circumvent limitations due to this thermal budget.

In one embodiment, the additional dopant is deposited in conjunction with the passivation layer deposition process, which can be comprised of a-Si, SiN, SiOx, SiOxNy or a combination thereof, preferably by the addition of a dopant containing gas in the deposition step. The dopant containing gases could for instance be PH3 or PF5, AsH3 or AsF5 in the case of an n-type front surface field, B2H6, BF3 or BCl3 in the case of a p-type front surface field. In another embodiment, the additional dopant may be implanted either before or after the application of the passivation layer.

Options for annealing an ex-situ front surface field are also provided. In each embodiment for bringing the desired dopant to the front surface, there are also several embodiments for activating the dopant, the first one being a laser anneal, preferably with a wavelength suitable to retain most heat close to the surface. Examples include but are not limited too, frequency-doubled or tripled Nd-YAG lasers, or in general lasers with wavelengths from the green to the UV range.

As an alternative, flood-exposing the surface with short wavelength light in order to promote free carrier absorption and promote absorption closer to the surface of the material even for a light source of longer wavelength may be performed.

The laser should not melt the surface, especially in the case that a pyramidal texture has been formed at some point prior to the annealing. If the laser does melt the surface, it should do so only in the top part of the surface so as to not have a detrimental effect on the light trapping quality of the textured surface.

A microwave cavity may also be used to activate dopants at reduced temperatures. In this embodiment, wafers are preferably put in a suitable batch microwave cavity and the annealing is subsequently carried out at the highest temperature that the reinforced structure will safely withstand.

Those with ordinary skill in the art will recognize that the disclosed embodiments have relevance to a wide variety of areas in addition to those specific examples described above.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

It is intended that all such additional systems, methods, features, and advantages that are included within this description be within the scope of the claims.

What is claimed is:

1. A method for making a thin film crystalline semiconductor substrate, said method comprising:
providing a reusable doped crystalline semiconductor template;
forming a porous semiconductor sacrificial seed and release layer on a front side of said reusable crystalline semiconductor template;
epitaxially depositing a thin film semiconductor substrate conformally to said sacrificial seed and release layer;
releasing said thin film semiconductor substrate from said reusable semiconductor template by separation at said porous semiconductor seed and layer; and
grinding the bevel of said reusable semiconductor substrate to remove residue of said released epitaxially deposited thin film semiconductor substrate.

2. The method of claim 1 wherein said grinding step is performed after each reuse of said reusable doped crystalline semiconductor template.

3. The method of claim 1 wherein said grinding step is performed once after a plurality of reuse cycles of said reusable doped crystalline semiconductor template.

4. The method of claim 1 wherein said reusable doped crystalline semiconductor template has an area in the range of at least 100 mm×100 mm up to about 300 mm×300 mm.

5. The method of claim 1 wherein said reusable doped crystalline semiconductor template and said epitaxially deposited thin film semiconductor substrate comprise the same semiconductor material.

6. The method of claim 1 wherein said reusable doped crystalline semiconductor template and said epitaxially deposited thin film semiconductor substrate comprise different semiconductor materials.

7. The method of claim 1, wherein at least one additional device processing steps are performed after said epitaxially depositing a thin film semiconductor substrate step and prior to said releasing process step.

8. The method of claim 1, wherein at least one additional device processing step is performed after said epitaxially depositing a thin film semiconductor substrate step and prior to said releasing process step.

9. The method of claim 1, wherein said epitaxially depositing a thickening layer of semiconductor material is performed once after a plurality of said epitaxially depositing a thin film semiconductor substrate and subsequently releasing said thin film semiconductor substrate process cycles.

10. The method of claim 1, wherein said thin film crystalline semiconductor substrate is used for fabrication of a solar cell.

11. The method of claim 1, wherein laser processing is utilized prior to said step of releasing said thin film semiconductor substrate from said reusable semiconductor template to cut through the semiconductor substrate and form the peripheral shape for said semiconductor substrate.

12. The method of claim 1, wherein said crystalline semiconductor comprises crystalline silicon.

13. The method of claim 12, wherein said crystalline silicon comprises monocrystalline silicon.

14. The method of claim 1, wherein said crystalline semiconductor comprises crystalline gallium arsenide.

15. The method of claim 1, wherein reusable doped crystalline semiconductor template has a tailored edge bevel.

16. The method of claim 1, wherein reusable doped crystalline semiconductor template has an asymmetric bevel.

17. The method of claim 1, where bevel grinding is performed on a plurality of reusable templates using parallel bevel grinding processing.

18. The method of claim 1, where in addition to bevel grinding, abrasive surface treatment such as grinding, lapping, polishing or chemical etching, including local chemical etching, is applied to a reusable template.

19. The method of claim 1, wherein said epitaxially deposited thin film semiconductor substrate is tailored to contain a variable dopant concentration throughout by using gas-switching and dopant to deposition gas mixture adjustment, said dopant concentration utilized to form beneficial layers such as front surface fields, back surface fields, or regions with suitable low base resistance.

20. The method of claim 1, wherein said reusable templates are marked with identifiers used to track template reuse cycles and processing information.

21. The method of claim 1, wherein said epitaxially deposited and later released substrate is defined using laser processing.

22. The method of claim 21, wherein said laser processing further comprises a laser ablation cutting process which at least partially cuts into the layer to be released in order to weaken the bond to the outside area of the deposited layer.

23. The method of claim 22, wherein said partial cut is subsequently extended to the porous semiconductor designated separation layer by mechanical means such as diamond scribing, water jet pressure or combinations thereof.

24. The method of claim 21, wherein said laser treatment is systematically adjusted during the laser process itself to accommodate thickness non-uniformities of the deposited layer.

25. The method of claim 21, wherein said laser treatment consists of a thermal laser separation step comprising applying local laser induced heating just outside the edge of the deposited substrate layer-to-be-released and followed by local cooling to generate a cleave front to separate the inside deposited layer area to be released from the outside deposited layer area to remain on the template during the main release process.

26. The method of claim 25, wherein said cleaving front is stopped in said porous semiconductor release layer.

27. The method of claim 1, further comprising the step of doping said epitaxially depositing thin film semiconductor substrate prior to release by applying a dopant source and subsequently applying a low effective thermal budget annealing process to form an ex-situ front surface field.

28. The method of claim 27, wherein said dopant source is applied by a deposited film.

29. The method of claim 27, wherein said dopant is applied by ion-implantation.

30. The method of claim 27, wherein said annealing process comprises laser processing.

31. The method of claim 27, wherein said annealing process comprises microwave annealing.
